(19) United States
(12) Patent Application Publication
(10) Pub. No.: US 2016/0064654 A1
(43) Pub. Date: Mar. 3, 2016

(54) SEMICONDUCTOR DEVICE AND A MANUFACTURING METHOD THEREOF

(71) Applicant: Renesas Electronics Corporation, Tokyo (JP)

(72) Inventors: Takashi Tonegawa, Tokyo (JP); Eiji Kariyada, Tokyo (JP); Takayasu Kazamatsuri, Tokyo (JP)

(73) Assignee: RENESAS ELECTRONICS CORPORATION

(21) Appl. No.: 14/829,595

(22) Filed: Aug. 18, 2015

(30) Foreign Application Priority Data
Aug. 26, 2014 (JP) 2014-172017

(51) Int. Cl. H01L 43/08; H01L 43/12; H01L 43/10

(52) U.S. Cl. CPC H01L 43/08; H01L 43/10; H01L 43/12

(57) ABSTRACT

The performances of a semiconductor device are improved. A semiconductor device has a conductive film formed above a semiconductor substrate, a first ferromagnetic film formed over the conductive film, an insulation film formed over the first ferromagnetic film, and a second ferromagnetic film formed over the insulation film. The first ferromagnetic film, the insulation film, and the second ferromagnetic film form a tunnel magnetoresistive effect element. The conductive film is formed of a metal nitride. The first ferromagnetic film contains cobalt, iron, and boron. The insulation film contains magnesium oxide.

### CROSS-REFERENCE TO RELATED APPLICATIONS

The disclosure of Japanese Patent Application No. 2014-172017 filed on Aug. 26, 2014 including the specification, drawings and abstract is incorporated herein by reference in its entirety.

### BACKGROUND

The present invention relates to a semiconductor device and a manufacturing method thereof, and is preferably applicable to, for example, a semiconductor device having a magnetic memory, and a manufacturing method thereof.

In a magnetic memory such as a Magnetic Random Access Memory: MRAM, a magnetoresistive effect element is used as a memory cell. A magnetoresistive effect element may have a Magnetic Tunnel Junction: MTJ in which a tunnel barrier layer is interposed between two layers of ferromagnetic layers. Further, in recent years, a semiconductor device including a magnetic memory element formed of a tunnel magnetoresistive effect element using a MTJ has been under development.

A magnetic memory element included in such a semiconductor device may include a tunnel barrier layer formed of a MgO (magnesium oxide) film as a tunnel barrier layer, and two layers of ferromagnetic layers each including a CoFeB (cobalt iron boron) film.

In Japanese Unexamined Patent Application Publication No. 2013-149857 (Patent Document 1), there is described a technology on a magnetoresistive effect element in which a MTJ is formed by a data storage layer including a CoFeB film, a tunnel barrier layer, and a data reference layer including a CoFeB film, and a magnetic memory.

### CITED DOCUMENT

### Patent Document

### Patent Document 1

### Japanese Unexamined Patent Application Publication No. 2013-149857

### SUMMARY

In a tunnel magnetoresistive effect element, when a ferromagnetic film containing Co (cobalt), Fe (iron), and B (boron) such as a CoFeB film, to be arranged in contact with a tunnel barrier layer formed of a MgO (magnesium oxide) film, has a body-centered cubic structure, and is in epitaxial contact with the tunnel barrier layer, the MR (Magneto-Resistance) ratio of the tunnel magnetoresistive effect element can be increased. However, when the conductive film serving as the base layer for the ferromagnetic film is formed of a metal such as Ta (tantalum), the conductive film formed of Ta tends to be crystallized. Accordingly, the ferromagnetic film formed over the conductive film is affected by the crystal structure of the conductive film, and hence, becomes less likely to have a body-centered cubic structure. In such a case, the MR ratio of the tunnel magnetoresistive effect element cannot be increased, resulting in the degradation of the performances of a semiconductor device having a magnetic memory element.

Other objects and novel features will be apparent from the description of this specification and the accompanying drawings.

In accordance with one embodiment, a semiconductor device has a conductive film formed over a semiconductor substrate, a first ferromagnetic film formed over the conductive film, an insulation film formed over the first ferromagnetic film, and a second ferromagnetic film formed over the insulation film. The first ferromagnetic film, the insulation film, and the second ferromagnetic film form a tunnel magnetoresistive effect element. The conductive film is formed of a metal nitride. The first ferromagnetic film contains cobalt, iron, and boron. The insulation film contains magnesium oxide.

Further, in accordance with another embodiment, a semiconductor device has a conductive film formed above a semiconductor substrate, a first ferromagnetic film formed over the conductive film, an insulation film formed over the first ferromagnetic film, and a second ferromagnetic film formed over the insulation film. The first ferromagnetic film, the insulation film, and the second ferromagnetic film form a tunnel magnetoresistive effect element. The conductive film is formed of a metal containing xenon. The first ferromagnetic film contains cobalt, iron, and boron. The insulation film contains magnesium oxide.

Furthermore, in accordance with a still other embodiment, with a method for manufacturing a semiconductor device, a conductive film formed of a metal or a metal nitride is formed above a semiconductor substrate. Then, the surface of the conductive film is reformed. Then, over the conductive film, there is formed a first ferromagnetic film containing cobalt, iron, and boron. Over the first ferromagnetic film, there is formed an insulation film containing magnesium oxide. Over the insulation film, there is formed a second ferromagnetic film. Further, after the formation of the insulation film, there is performed a heat treatment for crystallization of the first ferromagnetic film and the insulation film. The first ferromagnetic film, the insulation film, and the second ferromagnetic film form a tunnel magnetoresistive effect element.

In accordance with one embodiment, it is possible to improve the performances of the semiconductor device.

### BRIEF DESCRIPTION OF THE DRAWINGS

FIG. 1 is a cross sectional view showing a magnetic memory element of a semiconductor device of First Embodiment;

FIG. 2 is a cross sectional view showing a configuration of the semiconductor device of First Embodiment;

FIG. 3 is a circuit diagram showing a configuration of the semiconductor device of First Embodiment;

FIG. 4 is a view showing the direction of magnetization of a ferromagnetic film in a magnetic memory element of Second Embodiment;

FIG. 5 is a process flowchart showing some of the manufacturing steps of the semiconductor device of First Embodiment;

FIG. 6 is a cross sectional view showing the semiconductor device of First Embodiment during a manufacturing step;

FIG. 7 is a cross sectional view showing the semiconductor device of First Embodiment during a manufacturing step;

FIG. 8 is a cross sectional view showing the semiconductor device of First Embodiment during a manufacturing step;

FIG. 9 is a cross sectional view showing the semiconductor device of First Embodiment during a manufacturing step;

FIG. 10 is a cross sectional view showing the semiconductor device of First Embodiment during a manufacturing step;

FIG. 11 is a cross sectional view showing the semiconductor device of First Embodiment during a manufacturing step;

FIG. 12 is a graph showing the relationship between the material for a conductive film and the MR ratio;

FIG. 13 is a graph showing the relationship between the composition ratio of the conductive film and the MR ratio;

FIG. 14 is a cross sectional view showing a magnetic memory element of a semiconductor device of Second Embodiment;

FIG. 15 is a cross sectional view showing a configuration of the semiconductor device of Second Embodiment;

FIG. 16 is a view showing the direction of magnetization of each ferromagnetic film in the magnetic memory element of Second Embodiment;

FIG. 17 is a cross sectional view showing a magnetic memory element of a semiconductor device of a first modified example of Second Embodiment;

FIG. 18 is a cross sectional view showing a magnetic memory element of a semiconductor device of a second modified example of Second Embodiment;

FIG. 19 is a process flowchart showing some of the manufacturing steps of the semiconductor device of Second Embodiment;

FIG. 20 is a cross sectional view showing the semiconductor device of Second Embodiment during a manufacturing step;

FIG. 21 is a cross sectional view showing the semiconductor device of Second Embodiment during a manufacturing step;

FIG. 22 is a cross sectional view showing the semiconductor device of Second Embodiment during a manufacturing step;

FIG. 23 is a cross sectional view showing the semiconductor device of Second Embodiment during a manufacturing step;

FIG. 24 is a cross sectional view showing the semiconductor device of Second Embodiment during a manufacturing step;

FIG. 25 is a graph showing the relationship between the film thickness of the conductive film and the perpendicular magnetization of each ferromagnetic film;

FIG. 26 is a cross sectional view showing a magnetic memory element of a semiconductor device of Third Embodiment;

FIG. 27 is a view showing the direction of magnetization of each ferromagnetic film in the magnetic memory element of Third Embodiment; and

FIG. 28 is a cross sectional view showing the semiconductor device of Third Embodiment during a manufacturing step.

### DETAILED DESCRIPTION

In description of the following embodiment, the embodiment may be described in a plurality of divided sections or embodiments for convenience, if required. However, unless otherwise specified, these are not independent of each other, but are in a relation such that one is a modified example, details, a complementary explanation, or the like of a part or the whole of the other.

Further, in the following embodiments, when a reference is made to the number of elements, and the like (including number, numerical value, quantity, range, or the like), the number of elements is not limited to the specific number, but may be greater than or less than the specific number, unless otherwise specified, or except the case where the number is apparently limited to the specific number in principle.

Further in the following embodiments, it is needless to say that the constitutional elements (including element steps, or the like) are not always essential, unless otherwise specified, or except the case where they are apparently considered essential in principle, or except for other cases. Similarly, in the following embodiments, when a reference is made to the shapes, positional relationships, or the like of the constitutional elements, or the like, it is understood that they include ones substantially analogous or similar to the shapes or the like, unless otherwise specified, or unless otherwise considered apparently in principle, or except for other cases. This also applies to the foregoing numerical values and ranges.

Below, respective embodiments will be described in details by reference to the accompanying drawings. Incidentally, in all the drawings for describing the following embodiments, the members having the same function are given the same reference signs and numerals, and a repeated description thereon is omitted. Further, in the following embodiments, a description on the same or similar portions will not be repeated in principle, unless particularly required.

Further, in the accompanying drawings for use in the embodiments, hatching may be omitted even in cross section for ease of understanding of the drawings.

Further, in the following embodiments, when the range is shown as A to B, it is understood that the range shows A or more and B or less, unless otherwise specified.

### First Embodiment

Below, a semiconductor device of First Embodiment will be described in details by reference to the accompanying drawings.

<Configuration of Semiconductor Device>

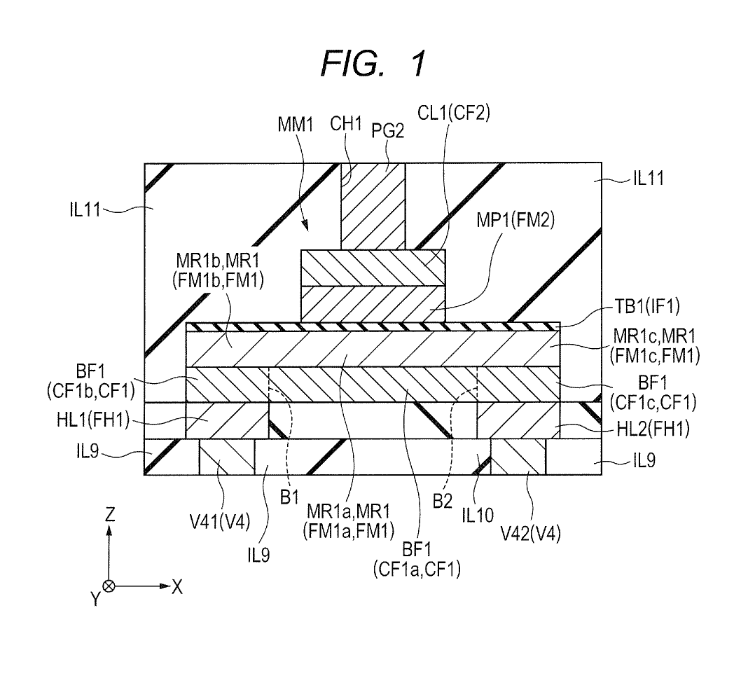

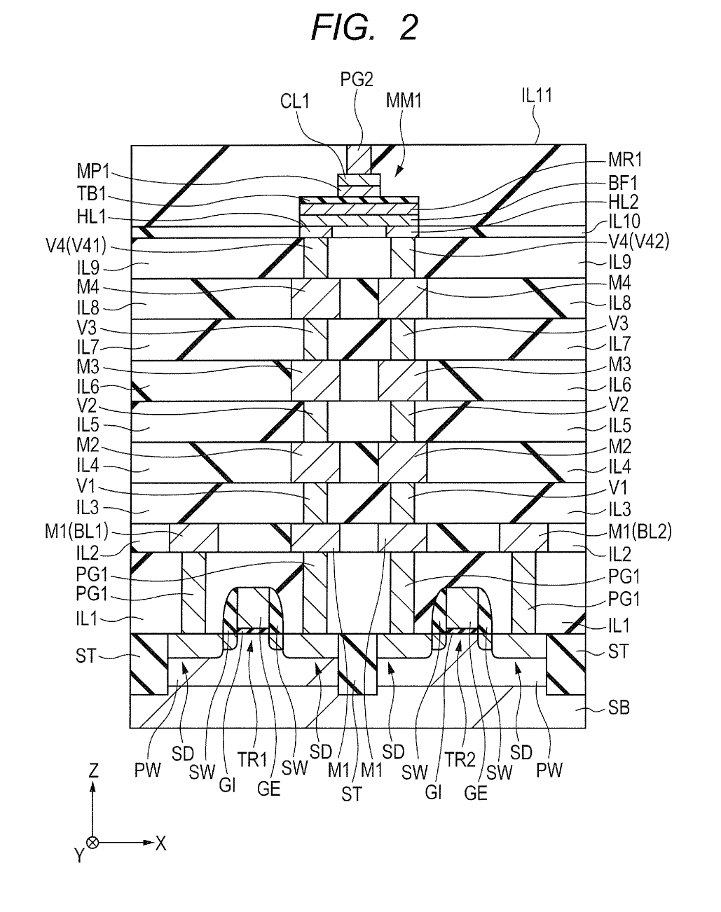

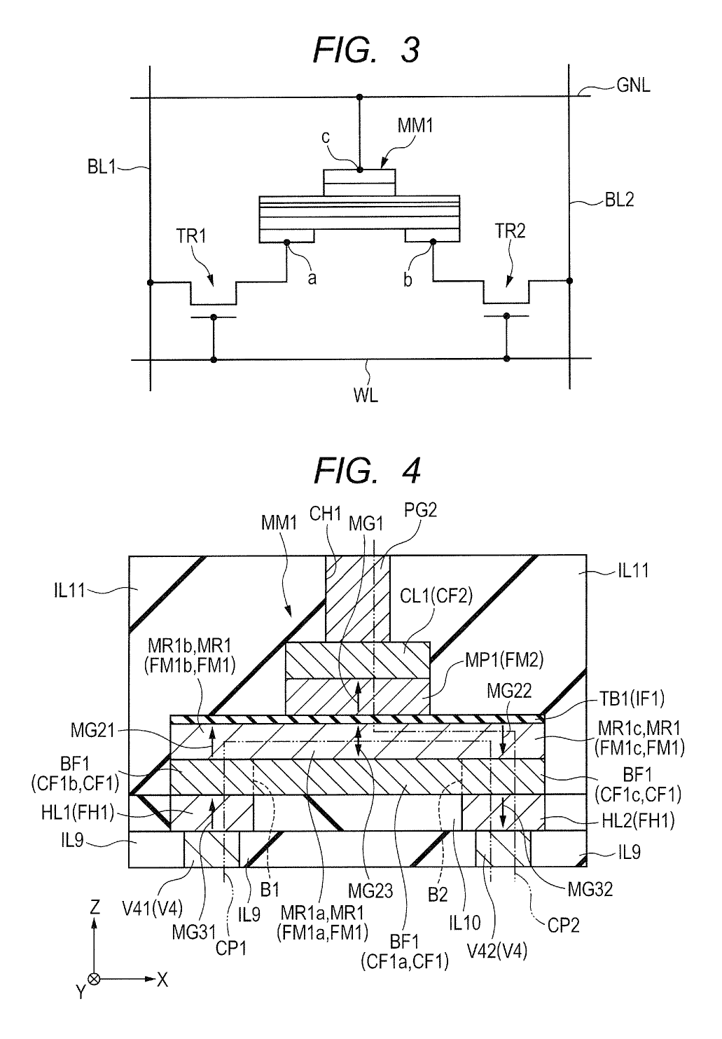

FIG. 1 is a cross sectional view showing a configuration of a magnetic memory element of a semiconductor device of First Embodiment. FIG. 2 is a cross sectional view showing a configuration of the semiconductor device of First Embodiment. FIG. 3 is a circuit diagram showing a configuration of the semiconductor device of First Embodiment. FIG. 4 is a view showing the direction of magnetization of each ferromagnetic film in the magnetic memory element of First Embodiment. Incidentally, in FIGS. 1, 2, and 4, the directions respectively in parallel with the main surface of a semiconductor substrate SB, and crossing each other are referred to as an X axis direction and a Y axis direction, respectively. The direction perpendicular to the main surface of the semiconductor substrate SB is referred to as a Z axis direction. Further, in FIG. 4, the magnetization direction in each of magnetization fixed layers HL1 and HL2, a magnetic recording layer MR1, and a magnetization fixed layer MP1 is schematically indicated with an arrow.

As shown in FIG. 1, the semiconductor device of the present First Embodiment has a magnetic memory element MM1 as a magnetic memory. The magnetic memory is a kind of nonvolatile memory, and is also referred to as a Magnetic Random Access Memory: MRAM. The magnetic memory has a ferromagnetic film having a magnetoresistive effect. Incidentally, the semiconductor device of the present First Embodiment is a domain wall displacement type MRAM.

The magnetic memory element MM1 shown in FIG. 1 is coupled in series between two selection transistors TR1 and TR2 as shown in, for example, FIGS. 2 and 3. Such a configuration is referred to as a 2T-1MTJ (2 Transistors-1 Magnetic Tunnel Junction) configuration. As shown in FIG. 3, the magnetic memory element MM1 has terminals a, b, and c as three terminals. The terminal c is coupled to a ground potential line GNL; the terminal a is coupled via the selection transistor TR1 to a bit line BL1; and the terminal b is coupled via the selection transistor TR2 to a bit line BL2. The terminal a corresponds to a magnetization fixed layer HL1 described later; the terminal b corresponds to a magnetization fixed layer HL2 described later; and the terminal c corresponds to a magnetization fixed layer MP1 described later.

Whereas, the gate electrodes of the selection transistors TR1 and TR2 are coupled to a word line WL, respectively. A plurality of such magnetic memory elements MM1 are arranged at intersection points of a pair of bit lines BL1 and BL2, and the word line WL, thereby to form a memory cell array.

<Selection Transistor>

As shown in FIG. 2, each of the selection transistors TR1 and TR2 is formed in a region defined by element isolation regions ST of the main surface of the semiconductor substrate SB, namely, the top surface of a p type well PW. Each of the selection transistors TR1 and TR2 has a gate electrode GE formed over the semiconductor substrate SB, namely, the p type well PW via a gate insulation film GI. Further, each of the selection transistors TR1 and TR2 has two semiconductor regions SD respectively provided in the upper layer parts of the semiconductor substrate SB, namely, the upper layer parts of the p type well PW at positions thereof situated on the opposite sides of the gate electrode GE, in a plan view. Of the two semiconductor regions SD, one functions as a source region, and the other functions as a drain region. At the sidewalls of the gate electrode GE, sidewall films SW are arranged, respectively. Each of the two semiconductor regions SD has a so-called LDD (Lightly Doped Drain) structure.

Each of the selection transistors TR1 and TR2 and the magnetic memory element MM1 are coupled via, for example, a plug PG1, a wire M1, a via part V1, a wire M2, a via part V2, a wire M3, a via part V3, a wire M4, and a via part V4. The plug PG1, the wire M1, the via part V1, the wire M2, the via part V2, the wire M3, the via part V3, the wire M4, and the via part V4 are formed in interlayer insulation films IL1 to IL9, respectively.

Specifically, of the two semiconductor regions SD of the selection transistor TR1, one semiconductor region SD is coupled via, for example, the plug PG1, the wire M1, the via part V1, the wire M2, the via part V2, the wire M3, the via part V3, the wire M4, and the via part V4 with the magnetization fixed layer HL1 of the magnetic memory element MM1. Whereas, of the two semiconductor regions SD of the selection transistor TR2, one semiconductor region SD is coupled via, for example, the plug PG1, the wire M1, the via part V1, the wire M2, the via part V2, the wire M3, the via part V3, the wire M4, and the via part V4 with the magnetization fixed layer HL2 of the magnetic memory element MM1. FIG. 2 shows an example in which the magnetic memory element MM1 is arranged over the via parts V4. However, the magnetic memory element MM1 is not arranged only over the via parts V4, and may be arranged over respective plugs, over respective wires, and over respective via parts.

Whereas, of the two semiconductor regions SD of the selection transistor TR1, the other semiconductor region SD is coupled via, for example the plug PG1 with the wire M1 serving as the bit line BL1. The other semiconductor region SD of the selection transistor TR2 is coupled via, for example, the plug PG1 with the wire M1 serving as the bit line BL2.

<Magnetic Memory Element>

As shown in FIG. 1, the magnetic memory element MM1 has a base layer BF1, a magnetic recording layer MR1, a tunnel barrier layer TB1, a magnetization fixed layer MP1, a cap layer CL1, and magnetization fixed layers HL1 and HL2. Above the semiconductor substrate SB, there is formed a base layer BF1. Over the base layer BF1, there is formed the magnetic recording layer MR1. Over the magnetic recording layer MR1, there is formed the tunnel barrier layer TB1.

Over the central part of the tunnel barrier layer TB1, there is formed the magnetization fixed layer MP1. Over the magnetization fixed layer MP1, there is formed the cap layer CL1. Under a portion of the base layer BF1 situated on one side of the central part thereof, there is formed the magnetization fixed layer HL1. Under a portion of the base layer BF1 situated on the other side of the central part thereof, the magnetization fixed layer HL2 is formed apart from the magnetization fixed layer HL1. The magnetic recording layer MR1, the tunnel barrier layer TB1, and the magnetization fixed layer MP1 form a MTJ. Namely, the magnetic recording layer MR1, the tunnel barrier layer TB1, and the magnetization fixed layer MP1 form a tunnel magnetoresistive effect element.

Herein, as shown in FIG. 1, in a plan view, the central part of the magnetic recording layer MR1 is referred to as a magnetization free region MR1a. Further, in a plan view, a portion of the magnetic recording layer MR1 situated on one side of the magnetization free region MR1a is referred to as a magnetization fixed region MR1b. In a plan view, a portion of the magnetic recording layer MR1 situated opposite to the magnetization fixed region MR1b across the magnetization free region MR1a is referred to as a magnetization fixed region MR1c. Namely, the magnetic recording layer MR1 includes the magnetization free region MR1a, the magnetization fixed region MR1b, and the magnetization fixed region MR1c. At this step, the magnetization fixed layer MP1 is formed over the magnetization free region MR1a via the tunnel barrier layer TB1.

The magnetization fixed region MR1b is a portion of the magnetic recording layer MR1 overlapping the magnetization fixed layer HL1 in a plan view. The magnetization fixed region MR1c is a portion of the magnetic recording layer MR1 overlapping the magnetization fixed layer HL2 in a plan view. The magnetization free region MR1a is a portion of the magnetic recording layer MR1 not overlapping either of the magnetization fixed layers HL1 and HL2 in a plan view. In other words, the magnetization free region MR1a is a portion of the magnetic recording layer MR1 situated between the magnetization fixed layer HL1 and the magnetization fixed layer HL2 in a plan view. The magnetization fixed layer MP1 is internally included in the magnetization free region MR1a in a plan view.

The magnetic recording layer MR1 is formed of a ferromagnetic film FM1. The magnetic recording layer MR1 forms a data storage layer. On the other hand, the magnetization fixed layer MP1 is formed of a ferromagnetic film FM2. The magnetization fixed layer MP1 forms a data reference layer. Alternatively, the ferromagnetic film FM2 may also be formed of a plurality of ferromagnetic layers.

Each of the ferromagnetic films FM1 and FM2 has a Perpendicular Magnetic Anisotropy: PMA. Namely, respective directions of magnetization ferromagnetic films FM1 and FM2 are directions in parallel with respective film thickness directions of the ferromagnetic films FM1 and FM2, and are directions perpendicular to respective top surfaces of the ferromagnetic films FM1 and FM2, respectively.

Each of the ferromagnetic films FM1 and FM2 contains Co (cobalt), Fe (iron), and B (boron). When such a ferromagnetic film containing Co, Fe, and B has a body-centered cubic structure, and is in epitaxial contact with the tunnel barrier layer TB1 formed of a MgO (magnesium oxide) film, the MR ratio of the tunnel magnetoresistive effect element can be increased. In other words, more preferably, each of the ferromagnetic films FM1 and FM2 is formed of a CoFeB film as a crystal film having a (100)-oriented body-centered cubic structure.

Herein, a consideration will be given to the case where the magnetization fixed layer MP1 includes other ferromagnetic films than the ferromagnetic film FM2. In such a case, of the ferromagnetic films included in the magnetization fixed layer MP1, ferromagnetic films other than the ferromagnetic film FM2 are each formed of a metal, or an alloy of two or more metals selected from, for example, Fe (iron), Co (cobalt), and Ni (nickel). Further, the ferromagnetic films may contain therein Pt (platinum) or Pd (palladium). This can stabilize the perpendicular magnetic anisotropy.

Further, to the ferromagnetic films other than the ferromagnetic film FM2 of the ferromagnetic films included in the magnetization fixed layer MP1, are added various elements such as B, C, N, O, Al, Si, P, Ti, V, Cr, Mn, Cu, Zn, Zr, Nb, Mo, Tc, Ru, Rh, Ag, Hf, Ta, W, Re, Os, Ir, Au, or Sm. As a result, the magnetic characteristics can be adjusted.

As the ferromagnetic films other than the ferromagnetic film FM2 of the ferromagnetic films included in the magnetization fixed layer MP1, there can be used specifically alloy films formed of materials such as Co, Co—Pt, Co—Pd, Co—Cr, Co—Pt—Cr, Co—Cr—Ta, Co—Cr—B, Co—Cr—Pt—B, or Co—Cr—Ta—B. Alternatively, there can be used alloy films formed of materials such as Co—V, Co—Mo, Co—W, Co—Ti, Co—Ru, Co—Rh, Fe—Pt, Fe—Pd, Fe—Co—Pt, Fe—Co—Pd, or Sm—Co.

Alternatively, the ferromagnetic films other than the ferromagnetic film FM2 of the ferromagnetic films included in the magnetization fixed layer MP1 may be a lamination film of films formed of the materials described above. For example, there may be used a lamination film of two or more metal films selected from, for example, Fe, Co, and Ni. Specifically, as the ferromagnetic film, there can be used a lamination film of Co/Ni, Co/Pd, Co/Pt, or Fe/Au. Incidentally, Co/Ni means a lamination film of a Co film and a Ni film.

The magnetization fixed layer MP1 may have a laminate in which a plurality of ferromagnetic films are stacked in such a manner as to interpose a non-magnetic film therebetween. For example, as the magnetization fixed layer MP1, there is formed a laminate in which a plurality of ferromagnetic films formed of the materials described above are formed in such a manner as to interpose a non-magnetic film formed of a Ru (ruthenium) film or the like therebetween. This can enhance the magnetic bonding force between a plurality of respective ferromagnetic films included in the magnetization fixed layer MP1, and produces an effect of enhancing the coercive force, namely, the antiferromagnetic bonding effect of the magnetization fixed layer MP1. Further, in such a laminate, a plurality of ferromagnetic films are kept with their respective magnetization directions pointing in the opposite directions to one another, namely, in antiparallel to one another. Accordingly, the leakage magnetic fields from mutual films are canceled. This can reduce the effect of the leakage magnetic fields from the magnetization fixed layer MP1.

The tunnel barrier layer TB1 is formed of an insulation film IF1. As described previously, the tunnel barrier layer TB1 is formed over the magnetization free region MR1a of the magnetic recording layer MR1.

Preferably, the insulation film IF1 contains MgO (magnesium oxide). When such an insulation film containing MgO has a rock-salt structure, namely, the insulation film has a face-centered cubic structure for each of Mg and O, a (100)-oriented MgO film can be formed with ease. In other words, more preferably, the insulation film IF1 is formed of a MgO film as a crystal film having a (100)-oriented rock-salt structure.

In the present First Embodiment, above the semiconductor substrate SB, there is formed a conductive film CF1. Over the conductive film CF1, there is formed a ferromagnetic film FM1. Over the ferromagnetic film FM1, there is formed an insulation film IF1. Over the insulation film IF1, there is formed a ferromagnetic film FM2. Then, the ferromagnetic film FM1, the insulation film IF1, and the ferromagnetic film FM2 form a tunnel magnetoresistive effect element.

The magnetization fixed layers HL1 and HL2 are each formed of a ferromagnetic film FH1. The magnetization fixed layers HL1 and HL2 each may have a base layer and a cap layer each formed of a metal film over and under the ferromagnetic film FH1. Use of the base layer produces an effect of enhancing the adhesion with the underlying insulation film, and the perpendicular magnetic anisotropy of the ferromagnetic film FH1. The cap layer produces an effect of preventing the processing damage on the ferromagnetic film FH1 during etching of the magnetization fixed layers HL1 and HL2. The ferromagnetic film FH1 has a perpendicular magnetic anisotropy. Namely, the direction of magnetization MG31 (see FIG. 4) of the magnetization fixed layer HL1 formed of the ferromagnetic film FH1 is a direction in parallel with the film thickness direction of the ferromagnetic film FH1, and a direction perpendicular to the top surface of the ferromagnetic film FH1. Whereas, the direction of magnetization MG32 (see FIG. 4) of the magnetization fixed layer HL2 formed of the ferromagnetic film FH1 is a direction in parallel with the film thickness direction of the ferromagnetic film FH1, and a direction perpendicular to the top surface of the ferromagnetic film FH1.

As the ferromagnetic films FH1, there can be used the same films as the ferromagnetic films other than the ferromagnetic film FM2 of the ferromagnetic films included in the magnetization fixed layer MP1. For example, the ferromagnetic film FH1 is formed of a metal or an alloy of two or more metals selected from, for example, Fe (iron), Co (cobalt), and Ni (nickel). Alternatively, the film may contain therein Pt (platinum) or Pd (palladium). This can stabilize the perpendicular magnetic anisotropy.

Further, to the ferromagnetic film FH1, are added various elements such as B, C, N, O, Al, Si, P, Ti, V, Cr, Mn, Cu, Zn, Zr, Nb, Mo, Tc, Ru, Rh, Ag, Hf, Ta, W, Re, Os, Ir, Au, or Sm. This can adjust the magnetic characteristics.

As the ferromagnetic film FH1, there can be used, specifically, an alloy film formed of a material such as Co, Co—Pt, Co—Pd, Co—Cr, Co—Pt—Cr, Co—Cr—Ta, Co—Cr—B, Co—Cr—Pt—B, or Co—Cr—Ta—B. Alternatively, there can be used an alloy film formed of a material such as Co—V, Co—Mo, Co—W, Co—Ti, Co—Ru, Co—Rh, Fe—Pt, Fe—Pd, Fe—Co—Pt, Fe—Co—Pd, or Sm—Co.

Alternatively, the ferromagnetic film FH1 may be a lamination film of films formed of the materials described above. There may be used a lamination film of two or more metal films selected from, for example, Fe, Co, and Ni. Specifically, as the ferromagnetic film FH1, there may be used a lamination film of Co/Ni, Co/Pd, Co/Pt, Fe/Au, or the like.

Still alternatively, as the ferromagnetic film FH1, there may be used a ferromagnetic film formed of the same material, or there may be used a ferromagnetic film formed of different materials. As shown in FIG. 4, the magnetization fixed layers HL1 and HL2 are formed so that respective magnetization directions of the magnetization fixed layers HL1 and HL2 are in antiparallel with each other. For the magnetization fixed layers HL1 and HL2, different ferromagnetic films may be used.

The magnetization fixed layer HL1 is formed over a via part V41 as the via part V4 embedded in the interlayer insulation film IL9, and is electrically coupled with the via part V41. The magnetization fixed layer HL2 is formed over a via part V42 as the via part V4 embedded in the interlayer insulation film IL9, and is electrically coupled with the via part V42. Over the interlayer insulation film IL9, the interlayer insulation film IL10 is formed in such a manner as to cover the via parts V41 and V42. The top surface of the interlayer insulation film IL10 is planarized. From the planarized top surface of the interlayer insulation film IL10, the magnetization fixed layers HL1 and HL2 are exposed, respectively.

The base layer BF1 is formed between the magnetic recording layer MR1 and the magnetization fixed layers HL1 and HL2. The base layer BF1 is formed of the conductive film CF1 as a non-magnetic conductive film.

Herein, as shown in FIG. 1, in a plan view, the central part of the base layer BF1, namely, the conductive film CF1 is referred to as a region CF1a. Whereas, in a plan view, a portion of the conductive film CF1 situated on one side of the region CF1a is referred to as a region CF1b. In a plan view, a portion of the conductive film CF1 situated opposite to the region CF1b across the region CF1a is referred to as a region CF1c. Namely, the conductive film CF1 includes the region CF1a, the region CF1b, and the region CF1c.

At this step, the magnetic recording layer MR1, namely, the ferromagnetic film FM1 includes a region FM1a formed over the region CF1a of the conductive film CF1, a region FM1b formed over the region CF1b of the conductive film CF1, and a region FM1c formed over the region CF1c of the conductive film CF1. Further, the magnetization free region MR1a is formed of the region FM1a. The magnetization fixed region MR1b is formed of the region FM1b. The magnetization fixed region MR1c is formed of the region FM1c.

Further, the magnetization fixed layer HL1 is formed under the region CF1b of the conductive film CF1. The magnetization fixed layer HL2 is formed under the region CF1c of the conductive film CF1.

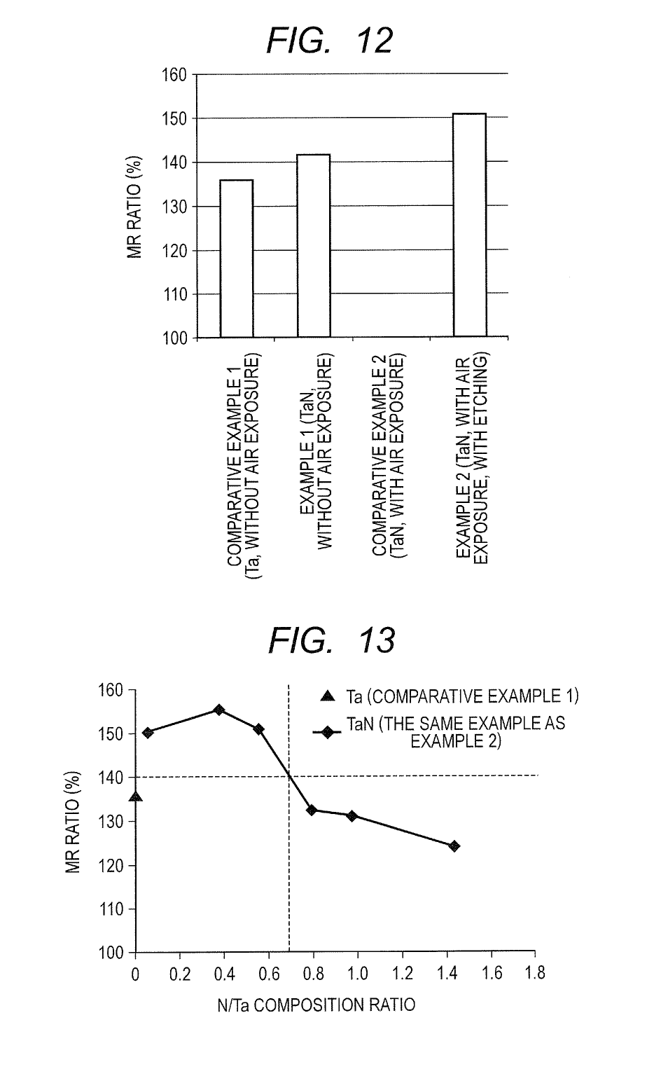

Preferably, the conductive film CF1 is formed of a metal nitride such as TaN (tantalum nitride). As a result, the conductive film CF1 becomes less likely to be crystallized. Therefore, as described by reference to FIG. 12 described later, the ferromagnetic film FM1 formed over the conductive film CF1 becomes less susceptible to the crystal structure of the conductive film CF1. On the other hand, the ferromagnetic film FM1 becomes more susceptible to the crystal structure of the insulation film IF1 formed over the ferromagnetic film FM1, and containing MgO. Therefore, the ferromagnetic film FM1 containing Co, Fe, and B can have a body-centered cubic structure along the crystal plane of the insulation film IF1 containing MgO. This can increase the MR ratio of the tunnel magnetoresistive effect element.

When the conductive film CF1 is formed of a metal nitride such as TaN (tantalum nitride), further, preferably, the conductive film CF1 is in an amorphous state, or in an insufficiently crystallized state. As a result, the conductive film CF1 becomes still less likely to be crystallized. Therefore, as described by reference to FIG. 12 described later, the ferromagnetic film FM1 formed over the conductive film CF1 becomes still less susceptible to the crystal structure of the conductive film CF1. On the other hand, the ferromagnetic film FM1 becomes still more susceptible to the crystal structure of the insulation film IF1 formed over the ferromagnetic film FM1, and containing MgO. Therefore, the ferromagnetic film FM1 containing Co, Fe, and B can have a body-centered cubic structure. This can increase the MR ratio of the tunnel magnetoresistive effect element.

Incidentally, the conductive film CF1 being in an amorphous state means the following case: when the intensity of the diffraction peak for the conductive film CF1 is measured with an X ray diffraction method, there is detected no any diffraction peak detected for a conductive film having the film thickness equal to that of the conductive film CF1, and being sufficiently crystallized. Whereas, the conductive film CF1 being in an insufficiently crystallized state means the following case: when the intensity of the diffraction peak for the conductive film CF1 is measured with an X ray diffraction method, the intensity of the diffraction peak is smaller than the diffraction peak detected for the conductive film having the film thickness equal to that of the conductive film CF1, and being sufficiently crystallized.

On the other hand, preferably, the conductive film CF1 is formed of a metal such as Ta (tantalum) in an amorphous state. Also in such a case, the conductive film CF1 becomes less likely to be crystallized. Therefore, as with the case where the conductive film CF1 is formed of a metal nitride, the ferromagnetic film FM1 formed over the conductive film CF1 becomes less susceptible to the crystal structure of the conductive film CF1. On the other hand, the ferromagnetic film FM1 becomes more susceptible to the crystal structure of the insulation film IF1 formed over the ferromagnetic film FM1, and containing MgO. Therefore, the ferromagnetic film FM1 containing Co, Fe, and B can have a body-centered cubic structure along the crystal plane of the insulation film IF1 containing MgO. This can increase the MR ratio of the tunnel magnetoresistive effect element.

When the conductive film CF1 is formed of a metal such as Ta (tantalum), further preferably, the conductive film CF1 is formed of, for example, a metal containing Xe (xenon). As a result, the conductive film CF1 becomes less likely to be crystallized. Accordingly, the MR ratio of the tunnel magnetoresistive effect element can be increased. Further, the specific resistance of the conductive film CF1 can be increased. For this reason, when a write current is passed between the magnetization fixed layer HL1 and the magnetization fixed layer HL2, a larger current can be passed through the magnetic recording layer MR1 of the magnetic recording layer MR1 and the base layer BF1. This can enhance the efficiency for writing data into the magnetic recording layer MR1.

The tunnel barrier layer TB1 is formed of the insulation film IF1. The tunnel barrier layer TB1 is formed over the magnetization free region MR1a, over the magnetization fixed region MR1b, and over the magnetization fixed region MR1c of the magnetic recording layer MR1. Namely, the insulation film IF1 is formed over the region FM1a of the ferromagnetic film FM1, over the region FM1b of the ferromagnetic film FM1, and over the region FM1c of the ferromagnetic film FM1. As a result, all of the region FM1a of the ferromagnetic film FM1, the region FM1b of the ferromagnetic film FM1, and the region FM1c of the ferromagnetic film FM1 can be made susceptible to the crystal structure of the insulation film IF1 containing MgO. Therefore, in all the magnetization free region MR1a, the magnetization fixed region MR1b, and the magnetization fixed region MR1c, the ferromagnetic film containing Co, Fe, and B can have a body-centered cubic structure along the crystal plane of the insulation film IF1 containing MgO. This can increase the MR ratio of the tunnel magnetoresistive effect element.

Incidentally, the magnetization fixed layer MP1 is formed of the ferromagnetic film FM2 at a portion thereof formed over the region FM1a of the ferromagnetic film FM1 via the insulation film IF1.

The insulation film IF1 contains, for example, MgO (magnesium oxide). When such an insulation film containing MgO is formed of a crystal film having a rock-salt structure, namely, when the insulation film is formed of a crystal film having a face-centered cubic structure for each of Mg and O, a (100)-oriented MgO film can be formed with ease.

Each film thickness of the magnetization fixed layers HL1 and HL2, namely, the film thickness including those of the ferromagnetic film FH1, the base layer, and the cap layer can be set at, for example, about 20 to 60 nm. Whereas, the film thickness of the base layer BF1, namely, the film thickness of the conductive film CF1 can be set at, for example, about 1 to 5 nm. On the other hand, the film thickness of the magnetic recording layer MR1, namely, the film thickness of the ferromagnetic film FM1 can be set at, for example, about 0.5 to 2 nm. Further, the film thickness of the tunnel barrier layer TB1, namely, the film thickness of the insulation film IF1 can be set at, for example, about 1 to 2 nm. Then, the film thickness of the magnetization fixed layer MP1, namely, the film thickness of the ferromagnetic film FM2 can be set at, for example, about 10 to 20 nm. Whereas, the film thickness of the conductive film CF2 can be set at, for example, about 20 to 70 nm.

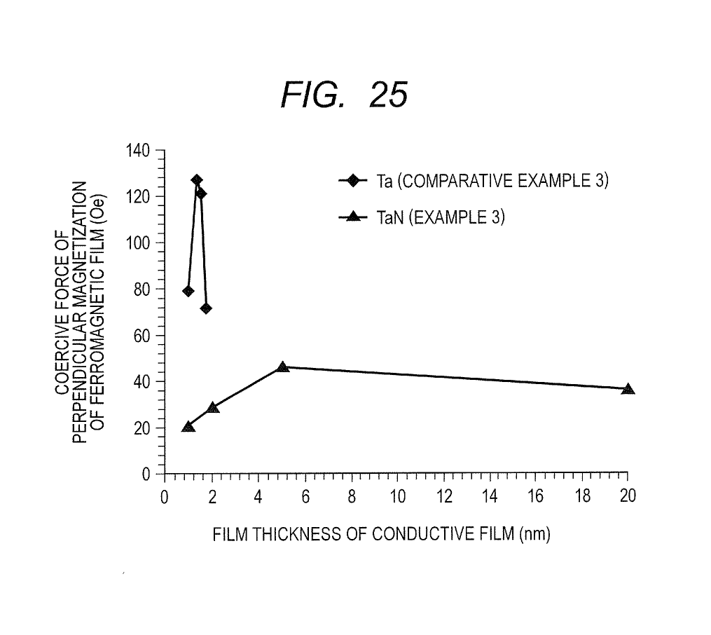

For the film thickness of the base layer BF1, namely, the film thickness of the conductive film CF1, in Second Embodiment, as described by reference to FIG. 25 described later, when the conductive film CF1 is formed of TaN, the film thickness of the conductive film CF1 can be set at, for example, about 1 to 20 nm. However, in the present First Embodiment, in the case where the film thickness of the conductive film CF1 exceeds 5 nm, when a write current is passed between the magnetization fixed layer HL1 and the magnetization fixed layer HL2, the current passed through the magnetic recording layer MR1 of the magnetic recording layer MR1 and the base layer BF1 is smaller. This may result in reduction of the efficiency when data is written into the magnetic recording layer MR1. Therefore, in the present First Embodiment, the film thickness of the conductive film CF1 is preferably, for example, about 1 to 5 nm.

The cap layer CL1 is formed of a conductive film CF2. As the conductive film CF2, there can be used the film formed of the same material as that for the conductive film CF1.

Over the interlayer insulation film IL10, an interlayer insulation film IL11 is formed in such a manner as to cover the base layer BF1, the magnetic recording layer MR1, the tunnel barrier layer TB1, the magnetization fixed layer MP1, and the cap layer CL1. In the top surface of the interlayer insulation film IL11, there is formed a contact hole CH1 penetrating through the interlayer insulation film IL11, and reaching the top surface of the cap layer CL1. In the inside of the contact hole CH1, there is formed a plug PG2 formed of a conductive film embedded in the inside of the contact hole CH1. Incidentally, although not shown in FIGS. 1 and 2, over the plug PG2 and over the interlayer insulation film IL11, there may be further formed a wire layer.

<Operation of Magnetic Memory Element>

As shown in FIG. 4, for example, the magnetization fixed layer MP1 has a magnetization MG1 fixed in the +Z axis direction. Further, by the magnetization fixed layer HL1, namely, the ferromagnetic film FH1, the direction of the magnetization MG21 of the magnetization fixed region MR1b of the magnetic recording layer MR1 is fixed in the +Z axis direction. By the magnetization fixed layer HL2, namely, the ferromagnetic film FH1, the direction of the magnetization MG22 of the magnetization fixed region MR1c of the magnetic recording layer MR1 is fixed in the −Z axis direction. Thus, the magnetization fixed region MR1b and the magnetization fixed region MR1c of the magnetic recording layer MR1 have magnetizations opposite in direction to each other, and in parallel with each other. In other words, the magnetization fixed region MR1c has a magnetization fixed in a direction in antiparallel with the magnetization included in the magnetization fixed region MR1b. On the other hand, the magnetization free region MR1a of the magnetic recording layer MR1 has a magnetization MG23 reversible between the +Z axis direction and the −Z axis direction.

Then, a description will be given to the write operation of data in the magnetic memory element MM1. Herein, the magnetization MG1 of the magnetization fixed layer MP1 is a magnetization fixed in the +Z axis direction; and the magnetization MG21 of the magnetization free region MR1a is a magnetization pointing in the −Z axis direction. Thus, the state in which a magnetic domain wall is formed at the border B1 between the magnetization fixed region MR1b and the magnetization free region MR1a is referred to as data “1”. Whereas, the magnetization of the magnetization fixed layer MP1 is a magnetization fixed in the +Z axis direction; and the magnetization of the magnetization free region MR1a is a magnetization pointing in the +Z axis direction. Thus, the state in which a magnetic domain wall is formed at the border B2 between the magnetization fixed region MR1c and the magnetization free region MR1a is referred to as data “0”. Incidentally, the correspondence between the magnetization direction and the value of data may be reversed.

When data “1” is written into the magnetic memory element MM1 with data “0” written therein, the write current is passed, for example, as indicated with a current path CP1 from the magnetization fixed layer HL1 via the magnetic recording layer MR1 in the direction of the magnetization fixed layer HL2. The write current injects spin-polarized electrons from the magnetization fixed region MR1c into the magnetization free region MR1a. At this step, the spin transfer effect moves the magnetic domain wall from the border B2 toward the border B1. Thus, the direction of the magnetization of the magnetization free region MR1a is changed from the +Z axis direction to the −Z axis direction.

When data “0” is written into the magnetic memory element MM1 with data “1” written therein, the write current is passed, for example, as indicated with the current path CP1, from the magnetization fixed layer HL2 via the magnetic recording layer MR1 in the direction of the magnetization fixed layer HL1. The write current injects spin-polarized electrons from the magnetization fixed region MR1b into the magnetization free region MR1a. At this step, the spin transfer effect moves the magnetic domain wall from the border B1 toward the border B2. Thus, the direction of magnetization of the magnetization free region MR1a is changed from the −Z axis direction to the +Z axis direction.

Namely, between the ferromagnetic film FH1 included in the magnetization fixed layer HL1 and the ferromagnetic film FH1 included in the magnetization fixed layer HL2, the write current is passed via the region FM1a of the ferromagnetic film FM1. This results in a change in magnetization MG23 of the region FM1a of the ferromagnetic film FM1.

Then, a description will be given to the read operation of data in the magnetic memory element MM1. Read is determined by whether the magnetic memory element MM1 is in a low resistance state, or in a high resistance state.

For example, in the state of data “1”, namely, when the magnetization of the magnetization fixed layer MP1 is a magnetization fixed in the +Z axis direction, and the magnetization of the magnetization free region MR1a is a magnetization pointing in the −Z axis direction, the resistance between the magnetization fixed layer MP1 and the magnetization free region MR1a is high. Namely, when the magnetization free region MR1a has a magnetization fixed in a direction in antiparallel with the direction of the magnetization of the magnetization fixed layer MP1, the resistance between the magnetization fixed layer MP1 and the magnetization free region MR1a is high. The resistance in this case is defined as a resistance R1.

Whereas, in the state of data “0”, namely, when the magnetization of the magnetization fixed layer MP1 is a magnetization fixed in the +Z axis direction, and the magnetization of the magnetization free region MR1a is a magnetization pointing in the +Z axis direction, the resistance between the magnetization fixed layer MP1 and the magnetization free region MR1a is low. Namely, when the magnetization free region MR1a has a magnetization fixed in a direction in parallel with the direction of the magnetization of the magnetization fixed layer MP1, the resistance between the magnetization fixed layer MP1 and the magnetization free region MR1a is low. The resistance in this case is defined as a resistance R0.

Accordingly, for example, as indicated with the current path CP2, a read current is passed between the magnetization fixed layer MP1 and the magnetization fixed layer HL2. Thus, the resistance value is detected by the current value flowing therebetween. For example, when the detected resistance value is higher than the reference resistance value, data “1” is read. For example, when the detected resistance value is lower than the reference resistance value, data “0” is read. In this manner, it is possible to determine the data written into the magnetic memory element MM1.

Incidentally, a read current may be passed between the magnetization fixed layer MP1 and the magnetization fixed layer HL1. Further, the read current may be passed from the magnetization fixed layer MP1 in the direction of the magnetization fixed layer HL1 or HL2. Alternatively, the current may be passed from the magnetization fixed layer HL1 or HL2 in the direction of the magnetization fixed layer MP1.

Whereas, as the ferromagnetic film FM2 included in the magnetization fixed layer MP1, the ferromagnetic film FH1 included in the magnetization fixed layer HL1, and the ferromagnetic film FH1 included in the magnetization fixed layer HL2, preferably, there is used ferromagnetic films having a higher coercive force than that of the magnetic recording layer MR1. The coercive force denotes the energy necessary for reversing the magnetization direction. As materials having relatively higher coercive force of the materials for the ferromagnetic film described previously, mention may be made of Co/Pt, Co/Pd, and the like.

As described previously, the resistance between the magnetization fixed layer MP1 and the magnetization free region MR1a when the magnetization free region MR1a has a magnetization MG23 fixed in a direction in antiparallel with the direction of the magnetization MG1 of the magnetization fixed layer MP1 is defined as a resistance R1. Whereas, the resistance between the magnetization fixed layer MP1 and the magnetization free region MR1a when the magnetization free region MR1a has a magnetization MG23 fixed in a direction in parallel with the direction of the magnetization MG1 of the magnetization fixed layer MP1 is defined as a resistance R0. In such a case, the ratio defined by, for example, (R1−R0)/R0 is referred to as a MR ratio. The larger the MR ratio, the larger the difference between the resistance R1 in a high resistance state and the resistance R0 in a low resistance state, resulting in an increase in sensing margin at the time of read.

In the present First Embodiment, the conductive film CF1 included in the base layer BF1 is formed of a metal nitride; the ferromagnetic film FM1 included in the magnetic recording layer MR1 is formed of a film containing Co, Fe, and B; and the insulation film IF1 included in the tunnel barrier layer TB1 is formed of a film containing MgO.

In such a case, by being affected by the crystal structure of the insulation film IF1 containing MgO, the ferromagnetic film FM1 containing Co, Fe, and B can be allowed to have a body-centered cubic structure. When, in the tunnel magnetoresistive effect element, the ferromagnetic film FM1 containing Co, Fe, and B arranged in contact with the tunnel barrier layer TB1 has a body-centered cubic structure along the crystal plane of the insulation film IF1 containing MgO, the MR ratio of the tunnel magnetoresistive effect element can be increased. Therefore, also in the semiconductor device of the present First Embodiment, the ferromagnetic film FM1 can have a body-centered cubic structure. This can increase the MR ratio of the tunnel magnetoresistive effect element formed of the magnetic recording layer MR1, the tunnel barrier layer TB1, and the magnetization fixed layer MP1.

<Method for Manufacturing a Semiconductor Device>

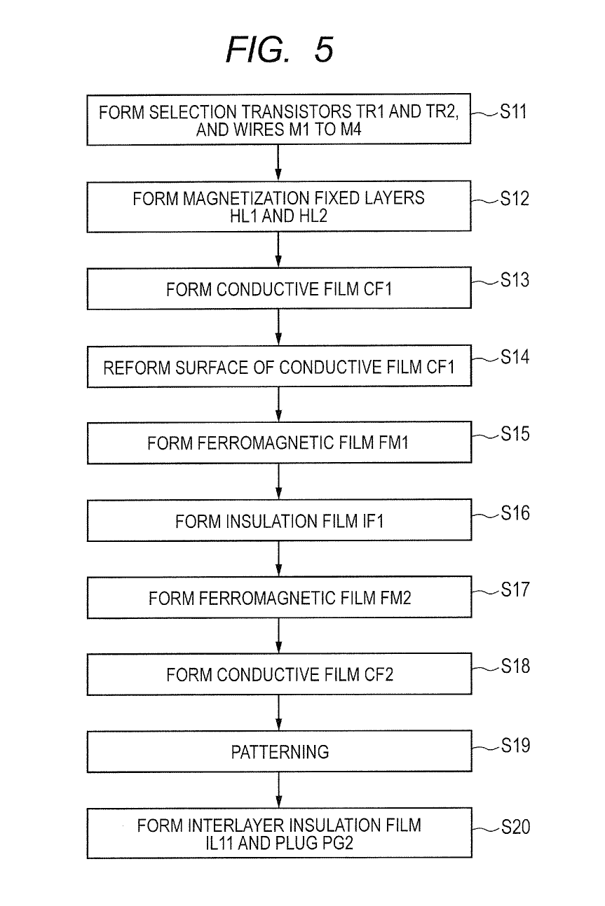

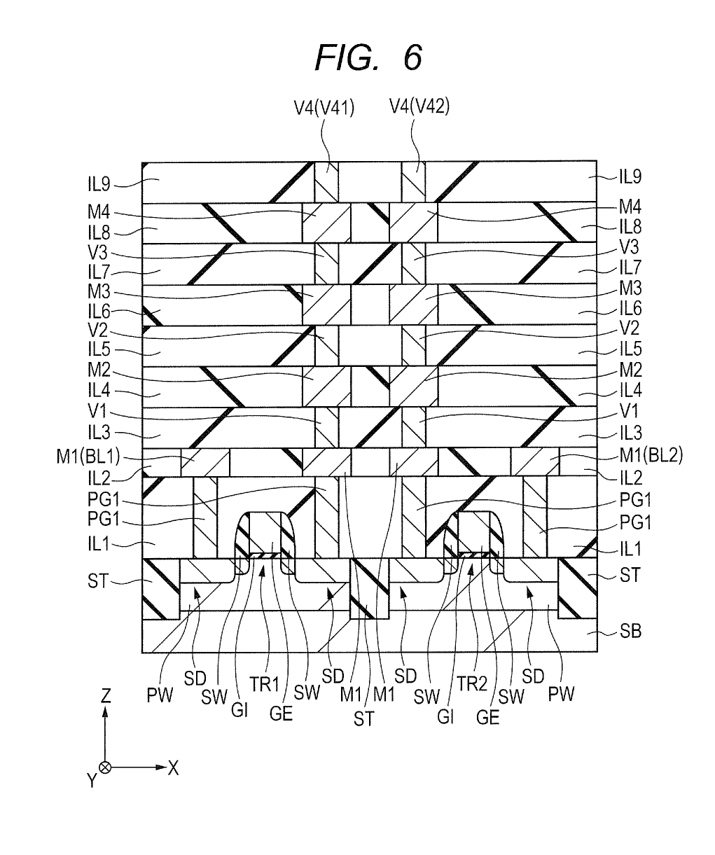

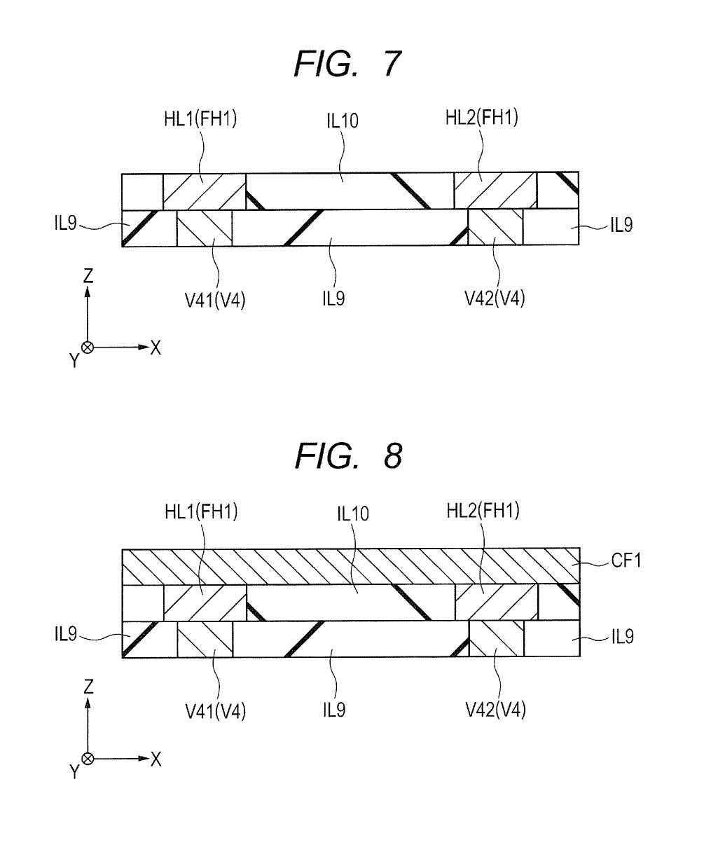

Then, with reference to FIGS. 5 to 11, a description will be given to a method for manufacturing the semiconductor device of the present First Embodiment. FIG. 5 is a process flowchart showing some of the manufacturing steps of the semiconductor device of First Embodiment. FIGS. 6 to 11 are each a cross sectional view showing the semiconductor device of First Embodiment during a manufacturing step. Of FIGS. 6 to 11, FIG. 6 is a cross sectional view showing a formation step of selection transistors TR1 and TR2, and wires M1 to M4; and FIGS. 7 to 11 are each a cross sectional view showing a formation step of the magnetic memory element MM1.

First, as shown in FIG. 6, at the main surface of the semiconductor substrate SB, there are formed two selection transistors TR1 and TR2. Further, over the selection transistors TR1 and TR2, there are formed a plurality of wires M1 to M4 (Step S11 of FIG. 5). The formation methods have no restriction. However, for example, the formation can be carried out by the following steps.

Further, a semiconductor substrate SB is provided. As the semiconductor substrate SB, there can be used a semiconductor substrate formed of, for example, a p type single crystal silicon having a specific resistance of about 1 to 10 Ωcm.

Then, in the main surface of the semiconductor substrate SB, there is formed an element isolation region ST. The element isolation region ST can be formed by, for example, a STI (Shallow Trench Isolation) method. In this case, the element isolation region of the semiconductor substrate SB is etched, thereby to form a trench. In the inside of the trench, an insulation film such as a silicon oxide film is embedded, thereby to form the element isolation region ST. For example, over the substrate including the inside of the trench, an insulation film such as a silicon oxide film is deposited. Using a Chemical Mechanical Polishing: CMP method, or the like, the portions of the insulation film except for the trenches are removed. As a result, the insulation film can be embedded in the inside of each trench.

The element isolation regions ST define an active region. In the active region, there are formed semiconductor elements such as the selection transistors TR1 and TR2. Each transistor herein is a field effect transistor also called a MISFET (Metal Insulator Semiconductor Field Effect Transistor). Incidentally, herein, a description will be given by taking an n channel type MISFET as an example. However, as a semiconductor element, there may be formed a p channel type MISFET obtained by reversing the conductivity type. Alternatively, both of an n channel type MISFET and a p channel type MISFET may be formed.

Then, in the active region of the semiconductor substrate SB, a p type well PW is formed. The p type well PW is formed by, for example, ion implanting a p type impurity into the semiconductor substrate SB. This can form the p type well PW which is a p type semiconductor region from the main surface of the semiconductor substrate SB to a prescribed depth.

Then, over the main surface of the semiconductor substrate SB, namely, over the top surface of the p type well PW, a gate electrode GE is formed via a gate insulation film GI. First, at the main surface of the semiconductor substrate SB, there is formed the gate insulation film GI formed of an insulation film. Using, for example, a thermal oxidation method, there is formed the gate insulation film GI formed of a silicon oxide film or the like.

Then, over the gate insulation film GI, a conductive film formed of, for example, polycrystal silicon is deposited using a CVD (Chemical Vapor Deposition) method, or the like. The conductive film is patterned into a desired shape, thereby to form the gate electrode GE. Patterning denotes the following: a photoresist film or the like in a desired shape is formed over a film using a photolithography technology; and using the photoresist film as a mask, the film is selectively etched, thereby to process the film into a desired shape.

Then, in the upper layer part of the semiconductor substrate SB at each portion thereof situated on the opposite sides of the gate electrode GE, there is formed a semiconductor region SD functioning as a source region or a drain region.

Further, by ion implantation using the gate electrode GE as a mask, there is formed each n⁻ type semiconductor region with a low impurity concentration. Then, over the semiconductor substrate SB including over the gate electrode GE, an insulation film formed of a silicon oxide film, or the like is formed, and is anisotropically etched. As a result, at each sidewall of the gate electrode GE, there is formed a sidewall film SW. Then, by ion implantation using the gate electrode GE and the sidewall films SW as a mask, there is formed each n⁺ type semiconductor region with a high impurity concentration. As a result, it is possible to form a semiconductor region SD of a LDD structure formed of an n⁻ type semiconductor region with a low impurity concentration, and an n⁺ type semiconductor region higher in impurity concentration, and deeper in junction depth than that.

Then, an annealing treatment, namely, a heat treatment is performed, so that the impurities injected by the ion implantation up to this point are activated.

By the steps up to this point, at the main surface of the semiconductor substrate SB, there can be formed semiconductor elements such as the selection transistors TR1 and TR2.

Then, using a salicide technology, at the upper parts of the gate electrode GE and the n⁺ type semiconductor region, there may be formed a metal silicide film (not shown). The metal silicide film can lower the diffusion resistance, the contact resistance, or the like.

Then, over the main surface of the semiconductor substrate SB, there is formed an interlayer insulation film IL1. An insulation film such as a silicon oxide film is deposited using a CVD method, or the like. Then, if required, using a CMP method, or the like, the surface of the insulation film is planarized.

Then, in the interlayer insulation film IL1, there are formed plugs PG1. First, the interlayer insulation film IL1 is etched, thereby to form contact holes. In each inside thereof, a conductive film is embedded, thereby to form a plug PG1. For example, over the interlayer insulation film IL1 including the inside of each contact hole, there is formed a lamination film of a barrier conductor film (not shown) and a main conductor film. The unnecessary portions of the film over the interlayer insulation film IL1 are removed by a CMP method, an etch back method, or the like.

Then, by a single damascene method, there is formed a first-layer wire M1. First, over the interlayer insulation film IL1 including the plugs PG1 embedded therein, there is formed an interlayer insulation film IL2. Then, by dry etching using a photoresist pattern (not shown) as a mask, wire trenches for the wire M1 are formed in prescribed regions of the interlayer insulation film IL2. Then, over the main surface of the semiconductor substrate SB, there is formed a barrier conductor film. As the barrier conductor film, there can be used, for example, a TiN (titanium nitride) film, a Ta (tantalum) film, or a TaN (tantalum nitride) film. Subsequently, by a CVD method, a sputtering method, or the like, a seed layer of copper is formed over the barrier conductor film. Further, using an electrolytic plating method, or the like, a copper plated film as a main conductor film is formed over the seed layer. As a result, the inside of the wire trench is filled with the copper plated film. Then, the portions of the copper plated film, the seed layer, and the barrier conductor film in the regions except for the wire trenches are removed by a CMP method. Accordingly, the copper plated film, the seed layer, and the barrier conductor film are left in the wire trenches. As a result, as shown in FIG. 6, the first-layer wire M1 including copper as amain conductive material is formed in each wire trench.

Incidentally, for simplification of the drawing, in FIG. 6, the copper plated film, the seed layer, and the barrier conductor film forming the wire M1 are integrally shown. The wire M1 is coupled to each plug PG1, and is electrically coupled with the semiconductor region SD, or the like via the plug PG1.

Then, a second-layer wire M2 and a via part V1 are formed by a single damascene method or a dual damascene method. Herein, a description will be given to the case of the single damascene method.

First, as shown in FIG. 6, over the interlayer insulation film IL2 including the wire M1 embedded therein, there is formed an interlayer insulation film IL3. Then, by dry etching using a photoresist pattern (not shown) as a mask, each via hole for a via part V1 is formed in a prescribed region of the interlayer insulation film IL3. Then, by the same procedure as that for the formation of the wire M1, the via hole for the via part V1 is filled with a conductive film mainly including copper. Then, the portions of the conductive film outside the via holes are removed by a CMP method, or the like. As a result, the conductive via part V1 is formed in the via hole. Then, over the interlayer insulation film IL3 including the via part V1 embedded therein, there is formed an interlayer insulation film IL4. Then, by the same procedure as that for the formation of the wire M1, each wire trench for the wire M2 is formed in the interlayer insulation film IL4. The wire trench is filled with a conductive film mainly including copper. Then, the portions of the conductive film outside the wire trenches are removed. As a result, the wire M2 is formed in each wire trench.

In the case of a dual damascene method, over the interlayer insulation film IL2 including the wire M1 embedded therein, the interlayer insulation films IL3 and IL4 are sequentially formed. Then, in the interlayer insulation films IL3 and IL4, there are formed each via hole for the via part V1 and each wire trench for the wire M2. The via hole and the wire trench are filled with a conductive film mainly including copper. Then, the portions of the conductive film outside the via hole and the wire trench are removed. As a result, the via part V1 and the wire M2 can be formed together, and the via part V1 is formed integrally with the wire M2.

With a single damascene method, the via part V1 and the wire M2 are formed separately. On the other hand, with a dual damascene method, the via part V1 and the wire M2 are formed integrally by the same step. In both the cases, the top surface of the via part V1 is coupled with the wire M2, and the bottom surface of the via part V1 is coupled with the wire M1. Accordingly, the wire M1 and the wire M2 can be electrically coupled with each other via the via part V1.

Then, by a single damascene method or a dual damascene method, a third-layer wire M3 and a via part V2 are formed. The procedure is the same as the procedure for forming the second-layer wire M2 and the via part V1.

As a result, over the interlayer insulation film IL4 including the wire M2 embedded therein, there is formed an interlayer insulation film IL5. Thus, a conductive via part V2 is formed in the via hole formed in the interlayer insulation film IL5. Over the interlayer insulation film IL5 including the via part V2 embedded therein, there is formed an interlayer insulation film IL6. Thus, a wire M3 is formed in the wire trench formed in the interlayer insulation film IL6.

Then, by a single damascene method or a dual damascene method, there are formed a fourth-layer wire M4 and a via part V3. The procedure is the same as the procedure for forming the third-layer wire M3 and the via part V2.

As a result, over the interlayer insulation film IL6 including the wire M3 embedded therein, there is formed an interlayer insulation film IL7. Thus, a conductive via part V3 is formed in each via hole formed in the interlayer insulation film IL7. Over the interlayer insulation film IL7 including the via part V3 embedded therein, there is formed an interlayer insulation film IL8. Thus, a wire M4 is formed in each wire trench formed in the interlayer insulation film IL8.

Then, by a single damascene method, there is formed each via part V4. The procedure for forming the via part V4 is the same procedure for forming the via part V1 by a single damascene method. Namely, over the interlayer insulation film IL8 including the wire M4 embedded therein, there is formed an interlayer insulation film IL9. Then, by dry etching using a photoresist pattern (not shown) as a mask, each via hole is formed in a prescribed region of the interlayer insulation film IL9. Then, the via hole is filled with a conductive film. Then, the portions of the conductive film outside the via holes are removed by a CMP method, or the like. Accordingly, the conductive film is left in each via hole, resulting in a via part V4. As a result, the conductive via part V4 can be formed in the via hole.

When the wires M2, M3, and M4 are copper wires, the via parts V1, V2, and V3 are also mainly formed of copper. The materials for the conductive film for the via part V4 may be mainly formed of copper, but are not limited thereto, and can be variously selected, if required. The via part V4 can also be regarded as a conductive plug.

By the steps up to this point, the selection transistors TR1 and TR2, and the wires M1 to M4 can be formed as shown in FIG. 6.

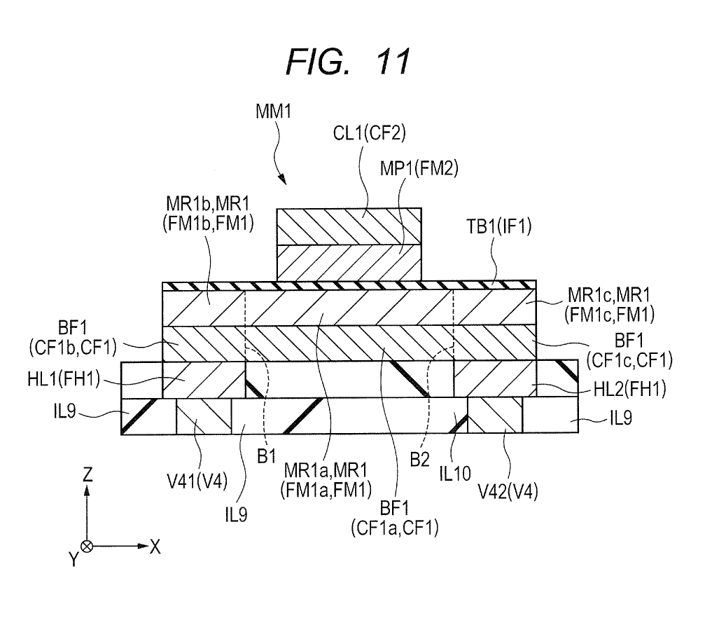

Then, over the interlayer insulation film IL9 including the via part V4 embedded therein, there is formed a magnetic memory element MM1 (see FIG. 11 described later).

First, as shown in FIG. 7, there are formed magnetization fixed layers HL1 and HL2 (Step S12 of FIG. 5).

In the Step S12, first, for example, over the interlayer insulation film IL9 including the via parts V41 and V42 as the via parts V4 embedded therein, a ferromagnetic film FH1 is deposited by a sputtering method, or the like. Then, the ferromagnetic film FH1 is patterned, thereby to form the magnetization fixed layers HL1 and HL2 each formed of the ferromagnetic film FH1.

The magnetization fixed layer HL1 is formed over the via part V41, and the magnetization fixed layer HL2 is formed over the via part V42. The via part V41 electrically coupled with the magnetization fixed layer HL1 is electrically coupled with one of the semiconductor regions SD of the selection transistor TR1 (see FIG. 6). Whereas, the via part V42 electrically coupled with the magnetization fixed layer HL2 is electrically coupled with one of the semiconductor regions SD of the selection transistor TR2 (see FIG. 6). The ferromagnetic film FH1 used as the magnetization fixed layers HL1 and HL2 is as described in the section of “magnetic memory element”.

Then, in Step S12, as shown in FIG. 7, over the magnetization fixed layers HL1 and HL2, there is formed an interlayer insulation film IL10. For example, over the magnetization fixed layers HL1 and HL2, and the interlayer insulation film IL9, an insulation film such as a silicon oxide film is deposited as the interlayer insulation film IL10 by a CVD method, or the like. Then, using a CMP method, an etch back method, or the like, the surface part of the interlayer insulation film IL10 is removed until the surfaces of the magnetization fixed layers HL1 and HL2 are exposed. As a result, as shown in FIG. 7, the magnetization fixed layers HL1 and HL2 are embedded in the interlayer insulation film IL10, and the surfaces of the magnetization fixed layers HL1 and HL2 are exposed from the surface of the interlayer insulation film IL10.

Then, as shown in FIG. 8, there is formed a conductive film CF1 (Step S13 of FIG. 5). In the Step S13, over the interlayer insulation film IL10 including the magnetization fixed layers HL1 and HL2 embedded therein, namely, above the semiconductor substrate SB, the conductive film CF1 for the base layer BF1 formed of a metal or a metal nitride is deposited by a sputtering method, or the like using a mixed gas of a mixture of an inert gas such as an Ar (argon) gas and a nitrogen gas. For example, the semiconductor substrate SB is arranged in the processing chamber included in a deposition treatment device, and the atmosphere in the processing chamber is reduced in pressure to a pressure lower than the atmospheric pressure, for example, a pressure of about 0.02 to 0.2 Pa. In this state, the conductive film CF1 can be deposited. Namely, in Step S13, with the semiconductor substrate SB not exposed to the air, the conductive film CF1 is formed over the semiconductor substrate SB.

Preferably, the conductive film CF1 is formed of a metal nitride such as TaN (tantalum nitride). As a result, the conductive film CF1 becomes less likely to be crystallized. Therefore, as described by reference to FIG. 12 described later, the ferromagnetic film FM1 (see FIG. 10 described later) formed over the conductive film CF1 using, for example, a sputtering method becomes less susceptible to the crystal structure of the conductive film CF1. On the other hand, the ferromagnetic film FM1 becomes more susceptible to the crystal structure of the insulation film IF1 formed over the ferromagnetic film FM1, and containing MgO (see FIG. 10 described later).

When the conductive film CF1 is formed of a metal nitride such as TaN, further preferably, the conductive film CF1 is in an amorphous state, or in an insufficiently crystallized state. There may be used WN (tungsten nitride), TiN (titanium nitride), or the like, in an amorphous state. As a result, the conductive film CF1 becomes still less likely to be crystallized. Therefore, as described by reference to FIG. 12 described later, the ferromagnetic film FM1 formed over the conductive film CF1 becomes still less susceptible to the crystal structure of the conductive film CF1. On the other hand, the ferromagnetic film FM1 becomes still more susceptible to the crystal structure of the insulation film IF1 formed over the ferromagnetic film FM1, and containing MgO.

Incidentally, the conductive film CF1 being in an amorphous state means the following case: when the intensity of the diffraction peak for the conductive film CF1 is measured with an X ray diffraction method, there is detected no any diffraction peak detected for a conductive film having the film thickness equal to that of the conductive film CF1, and being sufficiently crystallized. Whereas, the conductive film CF1 being in an insufficiently crystallized state means the following case: when the intensity of the diffraction peak for the conductive film CF1 is measured with an X ray diffraction method, the intensity of the diffraction peak is smaller than the diffraction peak detected for the conductive film having the film thickness equal to that of the conductive film CF1, and being sufficiently crystallized.

On the other hand, preferably, the conductive film CF1 is formed of a metal such as Ta (tantalum) in an amorphous state. Also in such a case, the conductive film CF1 becomes less likely to be crystallized. Therefore, as with the case where the conductive film CF1 is formed of a metal nitride, the ferromagnetic film FM1 formed over the conductive film CF1 becomes less susceptible to the crystal structure of the conductive film CF1. On the other hand, the ferromagnetic film FM1 becomes more susceptible to the crystal structure of the insulation film IF1 formed over the ferromagnetic film FM1, and containing MgO.

Further preferably, by a sputtering method using a Xe (xenon) gas as an inert gas, there is formed a conductive film CF1 formed of a metal such as Ta. Alternatively, by a sputtering method using a mixed gas of a mixture of a Xe (xenon) gas and a nitrogen gas as inert gases, there is formed the conductive film CF1 formed of a metal nitride such as TaN. At this step, the conductive film CF1 is formed of a metal or a metal nitride containing, for example, Xe (xenon). As a result, it is possible to increase the specific resistance of the base layer BF1 formed of the conductive film CF1. For this reason, when a write current is passed between the magnetization fixed layer HL1 and the magnetization fixed layer HL2, a larger current can be passed to the magnetic recording layer MR1 of the magnetic recording layer MR1 and the base layer BF1. This can enhance the efficiency for writing data into the magnetic recording layer MR1.

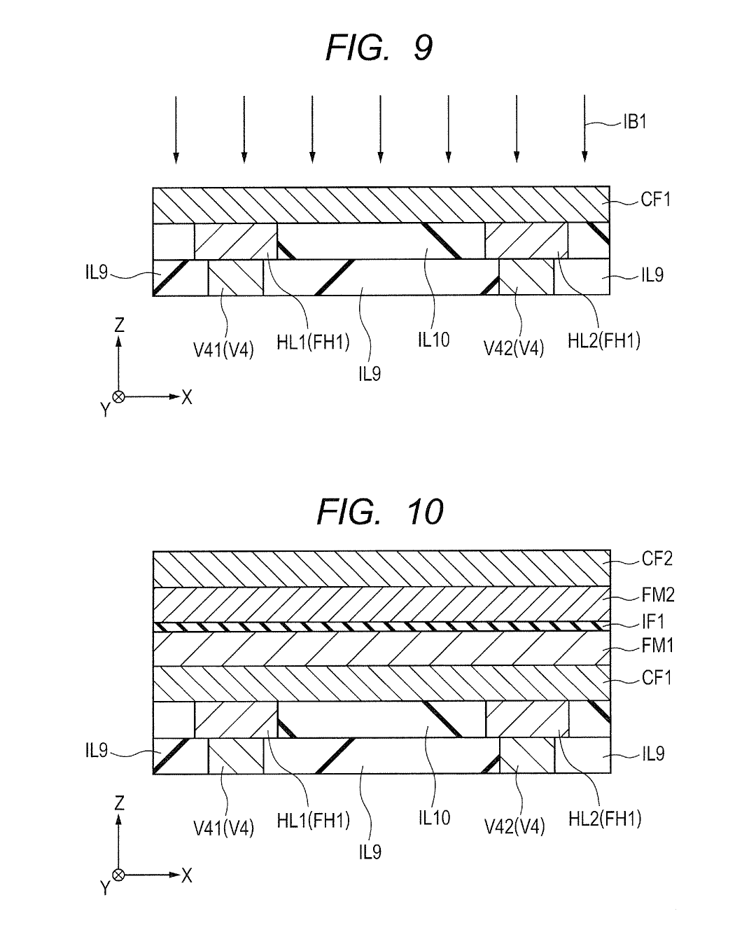

Then, as shown in FIG. 9, the surface of the conductive film CF1 is reformed. (Step S14 of FIG. 5).

In the Step S14, first, for example, the surface of the conductive film CF1 is exposed to the air. As a result, the surface of the conductive film CF1 is reformed (first reforming step). In the first reforming step, for example, the processing chamber included in the deposition treatment device used in the Step S13 is opened to the air. From the processing chamber, the semiconductor substrate SB is transported to the outside of the processing chamber. Thus, the surface of the conductive film CF1 is exposed to the air. As a result, the surface of the conductive film CF1 formed of, for example, TaN (tantalum nitride) is oxidized, so that a natural oxide layer is formed.

Further, in Step S14, after the first reforming step, as shown in FIG. 9, for example, the surface of the conductive film CF1 is etched. As a result, the surface of the conductive film CF1 is reformed (second reforming step). In the second reforming step, after the first reforming step, in the same or another processing chamber, the surface of the conductive film CF1 is subjected to physical etching by an ion beam IB1 of, for example, Ar⁺ (argon ion). As a result, the surface of the conductive film CF1 can be reformed. At this step, the natural oxide layer formed by oxidizing the surface of the conductive film CF1 formed of, for example, TaN (tantalum nitride) is removed by etching. Thus, the surface of the conductive film CF1 formed of TaN is rendered in a more amorphous state by physical etching. The etching amount of the conductive film CF1 formed of TaN in this case is preferably, for example, about 0.8 nm to 2 nm.

Alternatively, as a first modified example of Step S14, the following steps may also be performed.

In the first modified example of Step S14, first, for example, the surface of the conductive film CF1 is oxidized, so that the surface of the conductive film CF1 is reformed (the first modified example of the first reforming step). In the first modified example of the first reforming step, for example, after Step S13, the surface of the conductive film CF1 is not exposed to the air. However, by being exposed to an oxidizing atmosphere, or being subjected to a heat treatment in the same or another processing chamber, the surface of the conductive film CF1 is oxidized. As a result, an oxide layer is formed. Alternatively, by exposure into an oxygen plasma, a surface oxide layer may also be formed.

Further, in the first modified example of Step S14, after the first modified example of the first reforming step, the surface of the conductive film CF1 is etched. As a result, the surface of the conductive film CF1 is reformed (first modified example of the second reforming step). In the first modified example of the second reforming step, the same step as the second reforming step of Step S14 is performed, thereby to etch the oxide layer formed at the surface of the conductive film CF1. As a result, the surface of the conductive film CF1 can be reformed.

Alternatively, as a second modified example of Step S14, the following step can also be performed. In the second modified example of Step S14, the first modified example of the second reforming step is performed as the same step as the first modified example of the first reforming step. Namely, in the second modified example of Step S14, for example, the surface of the conductive film CF1 is etched while being oxidized. As a result, the surface of the conductive film CF1 is reformed. In other words, in the second modified example of Step S14, with the step of oxidizing the surface of the conductive film CF1, the step of etching the surface of the conductive film CF1 is performed. As a result, the surface of the conductive film CF1 is reformed.

Incidentally, in Step S13, for example, when the conductive film CF1 formed of a metal nitride in an amorphous state is formed, the surface reforming step of Step S14 is not required to be performed.

Then, as shown in FIG. 10, there is formed a ferromagnetic film FM1 (Step S15 of FIG. 5). In the Step S15, as shown in FIG. 10, over the conductive film CF1, a ferromagnetic film FM1 for a magnetic recording layer MR1 containing Co (cobalt), Fe (iron), and B (boron) such as a CoFeB (cobalt iron boron) film is deposited by a sputtering method, or the like.

The conductive film CF1 formed in the Step S14 is formed of a metal or a metal nitride, and is less likely to be crystallized. For this reason, the ferromagnetic film FM1 formed over the conductive film CF1 in Step S15 is less susceptible to the crystal structure of the conductive film CF1, and is, for example, in an amorphous state, or in an insufficiently crystallized state.

Then, as shown in FIG. 10, there is formed an insulation film IF1 (Step S16 of FIG. 5). In the Step S16, over the ferromagnetic film FM1, an insulation film IF1 containing MgO (magnesium oxide) is deposited by a RF sputtering method, or the like. The following is also acceptable: a metal Mg (magnesium) is deposited by a sputtering method; then, the Mg surface is oxidized, thereby to form MgO. The sputtering and oxidation of Mg may be repeated plural times for formation thereof. Alternatively, the sputtering and oxidation of Mg may be performed in different chambers (processing chambers), or may be performed in the same chamber.

MgO has a rock-salt structure, and has a face-centered cubic structure whether attention is paid to either atom of Mg (magnesium) and O (oxygen). When the insulation film IF1 containing MgO is formed, preferably, the insulation film IF1 is formed of a MgO film as a (100)-oriented crystal film.

Then, as shown in FIG. 10, there is formed a ferromagnetic film FM2 (Step S17 of FIG. 5). In the Step S17, over the insulation film IF1, a ferromagnetic film FM2 containing Co (cobalt), Fe (iron), and B (boron) such as a CoFeB (cobalt iron boron) film is deposited by a sputtering method, or the like. Incidentally, in Step S17, there may be formed a ferromagnetic film FM2 including a plurality of ferromagnetic layers.

Then, as shown in FIG. 10, there is formed a conductive film CF2 (Step S18 of FIG. 5). In the Step S18, over the ferromagnetic film FM2, the conductive film CF2 as a non-magnetic conductive film such as a Ta (tantalum) film is deposited by a sputtering method, or the like.

Then, as shown in FIG. 11, the conductive film CF2, the ferromagnetic film FM2, the insulation film IF1, the ferromagnetic film FM1, and the conductive film CF1 are patterned (Step S19 of FIG. 5).

In the Step S19, first, over the conductive film CF2, an insulation film such as a silicon oxide film (not shown) is formed by a CVD method. The insulation film is patterned. As a result, in a plan view, the insulation film is left in a region in which a magnetization free region MR1a, a magnetization fixed region MR1b, and a magnetization fixed region MR1c are formed. Then, using the insulation film (not shown) at a portion thereof left in the region in which the magnetization free region MR1a, the magnetization fixed region MR1b, and the magnetization fixed region MR1c are formed as a mask, there are etched the conductive film CF2, the ferromagnetic film FM2, the insulation film IF1, the ferromagnetic film FM1, and the conductive film CF1.

As a result, in the region in which the magnetization free region MR1a, magnetization fixed region MR1b, and the magnetization fixed region MR1c are formed, there are left the conductive film CF2, the ferromagnetic film FM2, the insulation film IF1, the ferromagnetic film FM1, and the conductive film CF1.

At this step, as shown in FIG. 11, there is formed a magnetic recording layer MR1 including the magnetization free region MR1a, the magnetization fixed region MR1b, and the magnetization fixed region MR1c, and formed of the ferromagnetic film FM1. Further, there is formed a base layer BF1 formed of the conductive film CF1 at a portion thereof left under the magnetization free region MR1a, the conductive film CF1 at a portion thereof left under the magnetization fixed region MR1b, and the conductive film CF1 at a portion thereof left under the magnetization fixed region MR1c. Further, there is formed a tunnel barrier layer TB1 formed of the insulation film IF1 at a portion thereof left over the magnetization free region MR1a, over the magnetization fixed region MR1b, and over the magnetization fixed region MR1c.

In other words, of the conductive film CF1, there are left a region CF1a, a region CF1b situated on one side of the region CF1a, and a region CF1c situated opposite to the region CF1b across the region CF1a. Whereas, of the ferromagnetic film FM1, there are left a region FM1a formed over the region CF1a of the conductive film CF1, a region FM1b formed over the region CF1b of the conductive film CF1, and a region FM1c formed over the region CF1c of the conductive film CF1. Then, there are formed a magnetization free region MR1a formed of the region FM1a, a magnetization fixed region MR1b formed of the region FM1b, and a magnetization fixed region MR1c formed of the region FM1c. Whereas, an insulation film IF1 is formed over the region FM1a of the ferromagnetic film FM1, over the region FM1b of the ferromagnetic film FM1, and over the region FM1c of the ferromagnetic film FM1.

Then, using a hard mask (not shown) formed of the insulation film at a portion thereof formed over the conductive film CF2, and left over the magnetization free region MR1a as a mask, the conductive film CF2 and the ferromagnetic film FM2 are etched. As a result, there are left the conductive film CF2 and the ferromagnetic film FM2 at respective portions thereof situated over the magnetization free region MR1a.

At this step, as shown in FIG. 11, there are formed a magnetization fixed layer MP1 formed of the ferromagnetic film FM2 at a portion thereof left over the magnetization free region MR1a, and a cap layer CL1 formed of the conductive film CF2 at a potion thereof left over the magnetization fixed layer MP1. Namely, there is formed the magnetization fixed layer MP1 formed of the ferromagnetic film FM2 at a portion thereof formed over the region FMla of the ferromagnetic film FM1 via the insulation film IF1.

Further, the magnetic recording layer MR1, the tunnel barrier layer TB1, and the magnetization fixed layer MP1 form a magnetic memory element MM1.

Then, there are formed an interlayer insulation film IL11 and a plug PG2 (Step S20 of FIG. 5).

In the Step S20, first, as shown in FIG. 1, over the interlayer insulation film IL10, an interlayer insulation film IL11 is formed in such a manner as to cover the base layer BF1, the magnetic recording layer MR1, the tunnel barrier layer TB1, the magnetization fixed layer MP1, and the cap layer CL1. As the interlayer insulation film IL11, an insulation film formed of, for example, a silicon oxide film is deposited by a CVD method, or the like.

Further, in Step S20, then, there is formed a contact hole CH1 penetrating through the interlayer insulation film IL11, and reaching the top surface of the cap layer CL1. Thus, a conductive film is formed in such a manner as to fill the inside of the contact hole CH1. As a result, as shown in FIG. 1, there is formed a plug PG2 formed of the conductive film embedded in the inside of the contact hole CH1.

Then, over the interlayer insulation film IL11, there is formed a wire (not shown). By the steps up to this point, as shown in FIG. 2, there can be formed the selection transistors TR1 and TR2, the wires M1 to M4, and the magnetic memory element MM1.

In the present First Embodiment, during manufacturing of a semiconductor device including the magnetic memory element MM1 after forming the insulation film IF1 containing MgO in Step S16, the semiconductor substrate SB is heat treated at a temperature of, for example, about 250 to 350° C. At this step, the ferromagnetic film FM1 is crystallized. For example, there are crystallized the ferromagnetic film FM1 containing Co, Fe, and B, and the insulation film IF1 containing MgO in an amorphous state, or in an insufficiently crystallized state. Namely, the manufacturing steps of the semiconductor device of the present First Embodiment has a step of performing a heat treatment for crystallization of the ferromagnetic film FM1 and the insulation film IF1 after the formation of the insulation film IF1. This step is not required to be a single step as a heat treatment step, and may be performed by heat history during deposition of, for example, the interlayer insulation film. Incidentally, the manufacturing steps of the semiconductor device of the present First Embodiment may also have a step of heat treating the semiconductor substrate SB at a temperature of, for example, about 250 to 350° C. after forming the insulation film IF1 in Step S16, and crystallizing the ferromagnetic film FM1 and the insulation film IF1 separately from other steps.

<Regarding the Relationship Between the Material for the Conductive Film and the MR Ratio>

FIG. 12 is a graph showing the relationship between the material for the conductive film and the MR ratio. In FIG. 12, as Comparative Example 1, the following case is shown: in the step corresponding to Step S13 of FIG. 5, a conductive film CF1 formed of Ta was formed, and air exposure as the surface reforming step of Step S14 of FIG. 5 was not performed. Further, in FIG. 12, as Example 1, the following case is shown: in the step corresponding to Step S13 of FIG. 5, a conductive film formed of TaN was formed, and air exposure as the surface reforming step of Step S14 of FIG. 5 was not performed.

Further, in FIG. 12, as Comparative Example 2, the following case is shown: in the step corresponding to Step S13 of FIG. 5, a conductive film CF1 formed of TaN was formed, and air exposure as the first reforming step of the surface reforming step of Step S14 of FIG. 5 was performed, so that the surface of the conductive film CF1 was exposed to the air, however, the second reforming step was not performed. Further, in FIG. 12, as Example 2, the following case is shown: in the step corresponding to Step S13 of FIG. 5, a conductive film CF1 formed of TaN was formed, and air exposure as the first reforming step of the surface reforming step of Step S14 of FIG. 5 was performed, so that the surface of the conductive film CF1 was exposed to the air; then, the second reforming step was performed, thereby to etch the surface of the conductive film CF1.

Incidentally, in Example 1, Comparative Example 2, and Example 2, the composition ratio of N to Ta was 0.56.

As shown in FIG. 12, in Example 1, the MR ratio was higher as compared with Comparative Example 1. Namely, when, after forming the conductive film CF1 formed of TaN, without performing the surface reforming step, the ferromagnetic film FM1 formed of a CoFeB film was formed, the MR ratio was higher than when, after forming the conductive film CF1 formed of Ta, without performing the surface reforming step, the ferromagnetic film FM1 formed of a CoFeB film was formed.

On the other hand, as shown in FIG. 12, in Comparative Example 2, the direction of magnetization in the ferromagnetic film FM1 was not perpendicular to the top surface of the ferromagnetic film FM1, but was in parallel with the top surface of the ferromagnetic film FM1. For this reason, in Comparative Example 2, the MR ratio was less than 100%.

Further, as shown in FIG. 12, also in Example 2, the MR ratio was higher as compared with Comparative Example 1. Namely, when after forming the conductive film CF1 formed of TaN, and performing the surface reforming step, the ferromagnetic film FM1 formed of a CoFeB film was formed, the MR ratio was higher than when, after forming the conductive film CF1 formed of Ta, without performing the surface reforming step, the ferromagnetic film FM1 formed of a CoFeB film was formed. Further, in Example 2, the MR ratio was higher even as compared with Example 1.

When, in the tunnel magnetoresistive effect element, the ferromagnetic film FM1 containing Co, Fe, and B arranged in contact with the tunnel barrier layer TB1 has a body-centered cubic structure, the MR ratio of the tunnel magnetoresistive effect element can be increased. However, when the conductive film CF1 is formed of a metal such as Ta, the conductive film CF1 formed of Ta tends to be crystallized. Accordingly, the ferromagnetic film FM1 formed over the conductive film CF1 is affected by the crystal structure of the conductive film CF1, and hence becomes less likely to have a body-centered cubic structure. In such a case, the MR ratio of the tunnel magnetoresistive effect element cannot be increased. This results in a deterioration of the performances of the semiconductor device including the magnetic memory element MM1.

On the other hand, when the conductive film CF1 is formed of a metal nitride such as TaN, the conductive film CF1 formed of TaN becomes less likely to be crystallized. After forming the conductive film CF1 in Step S13 until the next step is performed, the conductive film CF1 is in an amorphous state, or in an insufficiently crystallized state. Therefore, the ferromagnetic film FM1 formed over the conductive film CF1 becomes less susceptible to the crystal structure of the conductive film CF1, and, on the other hand, becomes more susceptible to the crystal structure of the insulation film IF1 formed over the ferromagnetic film FM1, and containing MgO.

Specifically, after forming the insulation film IF1 containing MgO over the conductive film CF1, a heat treatment is performed. As a result, from a portion of the ferromagnetic film FM1 in the vicinity of the interface between the ferromagnetic film FM1 and the insulation film IF1, the ferromagnetic film FM1 starts to be crystallized. For this reason, the ferromagnetic film FM1 can be formed as a crystal film having a body-centered cubic structure along the crystal plane of the insulation film IF1 containing MgO. Therefore, it is possible to increase the MR ratio of the magnetic memory element MM1 as a tunnel magnetoresistive effect element formed by the magnetic recording layer MR1 formed of the ferromagnetic film FM1, the tunnel barrier layer TB1 formed of the insulation film IF1, and the magnetization fixed layer MP1.

Preferably, the insulation film IF1 is formed of a MgO film having a (100)-oriented rock-salt structure. As a result, the ferromagnetic film FM1 can be formed as a crystal film formed of a CoFeB film having a (100)-oriented body-centered cubic structure.

<Regarding the Relationship Between the Composition Ratio of the Conductive Film and the MR Ratio>

FIG. 13 is a graph showing the relationship between the composition ratio of the conductive film and the MR ratio. FIG. 13 shows the following example, namely, the same example as Example 2: in the step corresponding to Step S13 of FIG. 5, a conductive film CF1 formed of TaN was formed, and the first reforming step of the surface reforming step of Step S14 of FIG. 5 was performed, so that the surface of the conductive film CF1 was exposed to the air; then, the second reforming step was performed, thereby to etch the surface of the conductive film CF1. Further, FIG. 13 shows Comparative Example 1 of FIG. 12. The horizontal axis of FIG. 13 denotes the N/Ta composition ratio, namely, the composition ratio of N to Ta as the composition ratio of the conductive film CF1.

As shown in FIG. 13, preferably, the composition ratio of nitrogen to tantalum in the conductive film CF1 formed of TaN is 0.06 to 0.7. As a result, the MR ratio is larger than 140%. For this reason, the MR ratio is sufficiently larger than the MR when the composition ratio of nitrogen to tantalum in the conductive film CF1 formed of TaN is 0, namely, when the conductive film CF1 is formed of Ta. Further preferably, the composition ratio of nitrogen to tantalum in the conductive film CF1 formed of TaN is 0.06 to 0.56.

<Regarding a Conductive Film Formed Using a Xe Gas>

As described previously, the conductive film CF1 formed by a sputtering method using a mixed gas of a Xe (xenon) gas and a nitrogen gas contains Xe. For example, when the conductive film CF1 formed by a sputtering method using a mixed gas of a Xe (xenon) gas and a nitrogen gas is formed of Ta or TaN, the content of Xe based on the amount of Ta or TaN in the conductive film CF1 was 0.2 to 2 at %.

Whereas, the MR ratio when the conductive film CF1 containing Xe was formed of Ta containing Xe in an amount of, for example, 0.2 to 2 at % was 152.7%, and was larger than the MR ratio when the conductive film CF1 was formed of Ta not containing Xe. Alternatively, the MR ratio when the conductive film CF1 was formed of TaN (N/Ta=0.49) containing Xe in an amount of, for example, 0.2 to 2 at % was 161.3%, and was larger than the MR ratio (155.4%) when the conductive film CF1 was formed of TaN (N/Ta=0.38) not containing Xe.

From the viewpoint of operating the domain wall displacement type MRAM at a low current, in order to efficiently pass a current through the magnetic recording layer MR1 for performing a data write operation, the specific resistance of the base layer BF1 is desirably high. Also from such a viewpoint, as the conductive film CF1 included in the base layer BF1, it is desirable to use the conductive film CF1 formed of Ta formed by a sputtering method using a Xe (xenon) gas. As compared with the conductive film CF1 formed of Ta formed by a sputtering method using an Ar (argon) gas, the conductive film CF1 formed of Ta formed by a sputtering method using a Xe gas is closer to the amorphous state, and is also higher in specific resistance. Whereas, the conductive film CF1 formed of Ta formed by a sputtering method using a Xe gas is formed of Ta containing Xe.

Specifically, the specific resistance of the conductive film CF1 formed of Ta formed by a sputtering method using an Ar gas was 197 μΩcm. On the other hand, the specific resistance of each conductive film CF1 formed of Ta formed by a sputtering method using a Xe gas under various conditions of different DC powers and gas flow rates was 244 to 377μΩcm, and was higher than the specific resistance of the conductive film CF1 formed of Ta formed by a sputtering method using an Ar gas. This can be considered due to the following: for example, the crystal state of the conductive film CF1 becomes closer to the amorphous state, resulting in a decrease in grain size of the conductive film CF1.

Thus, by increasing the specific resistance of the conductive film CF1, it is possible to pass a larger current through the magnetic recording layer MR1 relatively lower in specific resistance when a write current is passed between the magnetization fixed layer HL1 and the magnetization fixed layer HL2. For this reason, when data is written into the magnetic recording layer MR1, a current can be passed efficiently.

Incidentally, the specific resistance of the conductive film CF1 formed of TaN formed by a sputtering method using a Xe gas is also higher than the specific resistance of the conductive film CF1 formed of TaN formed by a sputtering method using an Ar gas. At this step, the conductive film CF1 formed of TaN formed by a sputtering method using a Xe gas is formed of TaN containing Xe.

Also in this case, by increasing the specific resistance of the conductive film CF1, it is possible to pass a larger current through the magnetic recording layer MR1 of the magnetic recording layer MR1 and the base layer BF1 when a write current is passed between the magnetization fixed layer HL1 and the magnetization fixed layer HL2. For this reason, when data is written into the magnetic recording layer MR1, a current can be passed efficiently.

<Main Features and Effects of the Present Embodiment>

The semiconductor device of the present First Embodiment has a conductive film CF1 formed above a semiconductor substrate, a ferromagnetic film FM1 formed over the conductive film CF1, an insulation film IF1 formed over the ferromagnetic film FM1, and a ferromagnetic film FM2 formed over the insulation film IF1. The ferromagnetic film FM1, the insulation film IF1, and the ferromagnetic film FM2 form the magnetic memory element MM1 as a tunnel magnetoresistive effect element. The conductive film CF1 is formed of a metal nitride, or a metal containing Xe. The ferromagnetic film FM1 contains Co, Fe, and B. The insulation film IF1 contains MgO.

In such a case, by being affected by the crystal structure of the insulation film IF1 containing MgO, the ferromagnetic film FM1 containing Co, Fe, and B can be formed to have a body-centered cubic structure along the crystal plane of the insulation film IF1 containing MgO. When, in the magnetic memory element MM1 as a tunnel magnetoresistive effect element, the ferromagnetic film FM1 containing Co, Fe, and B arranged in contact with the tunnel barrier layer TB1 has a body-centered cubic structure, the MR ratio of the magnetic memory element MM1 as a tunnel magnetoresistive effect element can be increased. Therefore, also in the semiconductor device of the present First Embodiment, the ferromagnetic film FM1 can have a body-centered cubic structure. This can increase the MR ratio of the tunnel magnetoresistive effect element formed of the ferromagnetic film FM1, the insulation film IF1, and the ferromagnetic film FM2. For this reason, it is possible to improve the performances of the semiconductor device including the magnetic memory element MM1.

### Second Embodiment

In First Embodiment, a description has been given to the applied example to the domain wall displacement type MRAM. In contrast, in Second Embodiment, a description will be given to an applied example to a MRAM (STT-MRAM) using Spin Transfer Torque: STT.

<Configuration of Semiconductor Device>

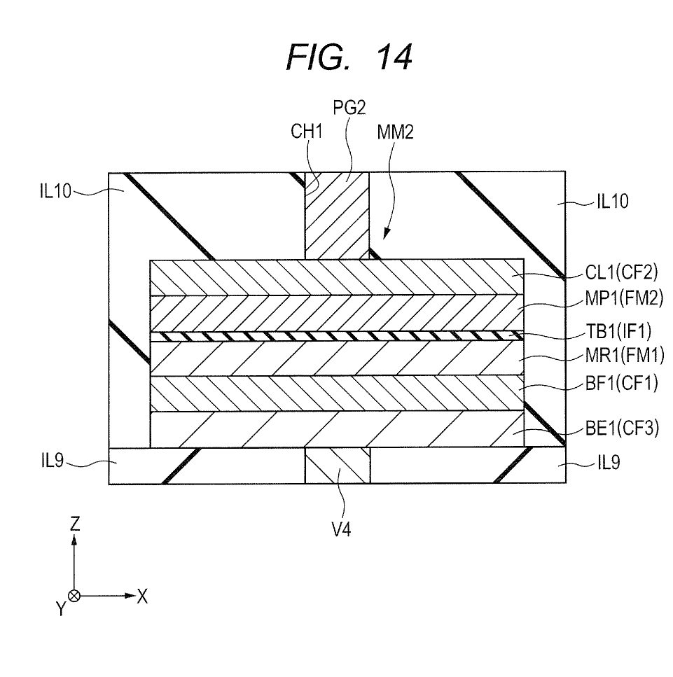

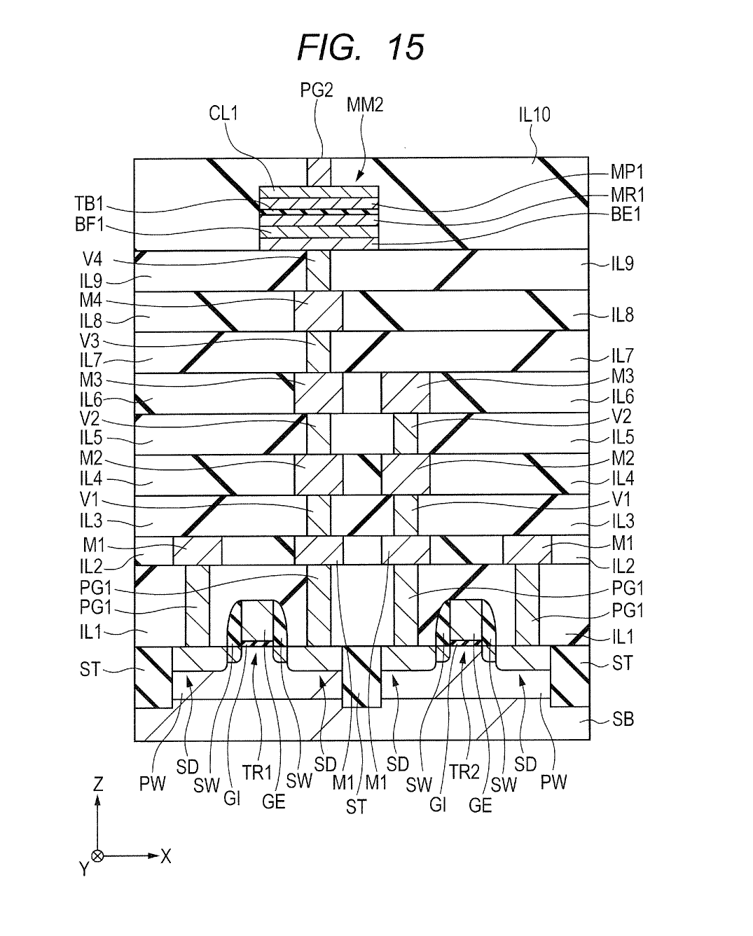

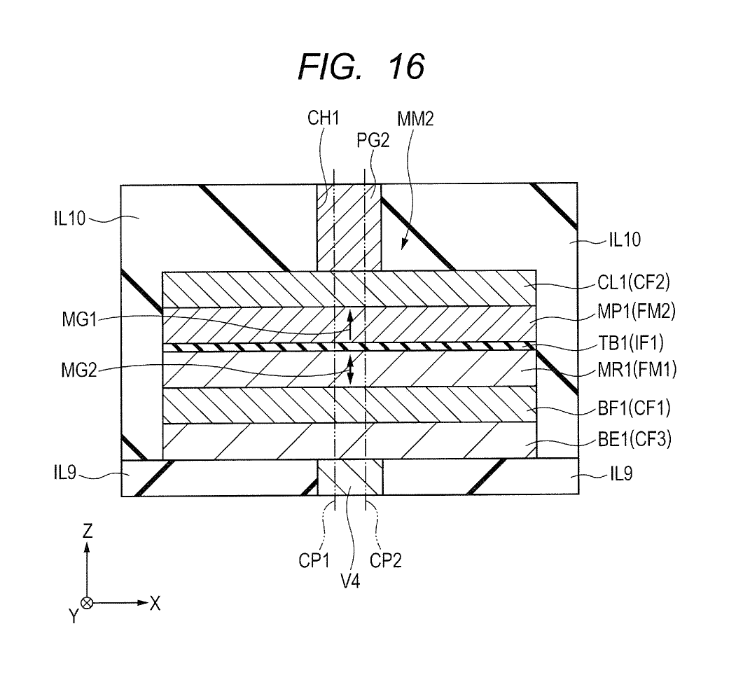

FIG. 14 is a cross sectional view showing a magnetic memory element of a semiconductor device of Second Embodiment. FIG. 15 is a cross sectional view showing a configuration of the semiconductor device of Second Embodiment. FIG. 16 is a view showing the direction of magnetization of each ferromagnetic film in a magnetic memory element of Second Embodiment. Incidentally, in FIG. 16, the magnetization direction in each of the magnetic recording layer MR1 and the magnetization fixed layer MP1 is schematically indicated with an arrow.

One end of a magnetic memory element MM2 shown in FIG. 14 is coupled in series to one selection transistor TR1 as shown in, for example, FIG. 15. Whereas, the other end of the magnetic memory element MM2 is coupled via a plug PG2 to a bit line (not shown). As shown in FIG. 15, the portion of the semiconductor device below the magnetic memory element MM2 in the present Second Embodiment can be configured almost the same as the portion of the semiconductor device below the magnetic memory element MM1 in First Embodiment. Whereas, the selection transistors TR1 and TR2 in the present Second Embodiment shown in FIG. 15 can also be configured the same as the selection transistors TR1 and TR2 in First Embodiment described by reference to FIG. 2, respectively.

<Magnetic Memory Element>

As shown in FIG. 14, the magnetic memory element MM2 has a base layer BF1, a magnetic recording layer MR1, a tunnel barrier layer TB1, a magnetization fixed layer MP1, a cap layer CL1, and a bottom electrode layer BE1. Above the semiconductor substrate SB, there is formed the base layer BF1. Over the base layer BF1, there is formed the magnetic recording layer MR1. Over the magnetic recording layer MR1, there is formed the tunnel barrier layer TB1. Over the tunnel barrier layer TB1, there is formed the magnetization fixed layer MP1. Over the magnetization fixed layer MP1, there is formed the cap layer CL1.

Under the base layer BF1, there is formed the bottom electrode layer BE1. The magnetic recording layer MR1, the tunnel barrier layer TB1, and the magnetization fixed layer MP1 form a MTJ. Namely, the magnetic recording layer MR1, the tunnel barrier layer TB1, and the magnetization fixed layer MP1 form a tunnel magnetoresistive effect element.

The magnetic recording layer MR1 is formed of a ferromagnetic film FM1. The magnetic recording layer MR1 forms a data storage layer. On the other hand, the magnetization fixed layer MP1 is formed of a ferromagnetic film FM2. The magnetization fixed layer MP1 forms a data reference layer. Alternatively, the ferromagnetic film FM2 may also be formed of a plurality of ferromagnetic layers.

Each of the ferromagnetic films FM1 and FM2 has a perpendicular magnetic anisotropy. Namely, respective directions of magnetization of the ferromagnetic films FM1 and FM2 are directions in parallel with respective film thickness directions of the ferromagnetic films FM1 and FM2, and are directions perpendicular to respective top surfaces of the ferromagnetic films FM1 and FM2, respectively.

The ferromagnetic films FM1 and FM2 in the present Second Embodiment can also be configured the same as the ferromagnetic films FM1 and FM2 of First Embodiment, respectively. Therefore, also in the present Second Embodiment, as with First Embodiment, each of the ferromagnetic films FM1 and FM2 contains Co (cobalt), Fe (iron), and B (boron). When such a ferromagnetic film containing Co, Fe, and B has a body-centered cubic structure, the MR ratio of the tunnel magnetoresistive effect element can be increased.

Incidentally, when the magnetization fixed layer MP1 includes other ferromagnetic films than the ferromagnetic film FM2, of the ferromagnetic films included in the magnetization fixed layer MP1, other ferromagnetic films than the ferromagnetic film FM2 can be configured the same as those in First Embodiment.

The tunnel barrier layer TB1 is formed of an insulation film IF1. The insulation film IF1 in the present Second Embodiment can also be configured the same as the insulation film IF1 of First Embodiment. Preferably, the insulation film IF1 contains MgO (magnesium oxide).

Also in the present Second Embodiment, as with First Embodiment, above the semiconductor substrate SB, there is formed a conductive film CF1. Over the conductive film CF1, there is formed a ferromagnetic film FM1. Over the ferromagnetic film FM1, there is formed an insulation film IF1. Over the insulation film IF1, there is formed a ferromagnetic film FM2. Then, the ferromagnetic film FM1, the insulation film IF1, and the ferromagnetic film FM2 form a tunnel magnetoresistive effect element.

The bottom electrode layer BE1 is formed over a via part V4 embedded in the interlayer insulation film IL9, and is electrically coupled with the via part V4. The bottom electrode layer BE1 is formed of a conductive film CF3. As the conductive film CF3, there can be used a conductive film of, for example, Ta (tantalum), TaN (tantalum nitride), Ru (ruthenium), Pt (platinum), Ti (titanium), or TiN (titanium nitride). Alternatively, as the conductive film CF3, there may be used a conductive film formed of a lamination film of Ta, Ru, and Ta.

The base layer BF1 is formed between the magnetic recording layer MR1 and the bottom electrode layer BE1. The base layer BF1 is formed of the conductive film CF1 as a non-magnetic conductive film.

The conductive film CF1 in the present Second Embodiment can also be configured the same as the conductive film CF1 of First Embodiment. Therefore, for example, preferably, the conductive film CF1 is formed of a metal nitride, or a metal in an amorphous state. As a result, the conductive film CF1 becomes less likely to be crystallized. For this reason, the ferromagnetic film FM1 formed over the conductive film CF1 becomes less susceptible to the crystal structure of the conductive film CF1. On the other hand, the ferromagnetic film FM1 becomes more susceptible to the crystal structure of the insulation film IF1 formed over the ferromagnetic film FM1, and containing MgO.

Incidentally, in the present Second Embodiment, the magnetic memory element MM2 is a tunnel magnetoresistive effect element included in a STT-MRAM, and hence, as distinct from First Embodiment, less produces the following effect: by increasing the specific resistance of the conductive film CF1, a larger current is passed efficiently for writing data into the magnetic recording layer MR1. Therefore, even when the conductive film CF1 is formed of a metal such as Ta (tantalum), it is not required to be formed of a metal containing Xe (xenon).

<Operation of Magnetic Memory Element>

As shown in FIG. 16, for example, the magnetization fixed layer MP1, namely, the ferromagnetic film FM2 has a magnetization MG1 fixed in the +Z axis direction. On the other hand, the magnetic recording layer MR1, namely, the ferromagnetic film FM1 has a magnetization MG2 reversible between the +Z axis direction and the −Z axis direction.

Then, a description will be given to the write operation of data in the magnetic memory element MM2. Also in the present Second Embodiment, as with First Embodiment, the following state is referred to as data “1”: the magnetization MG1 of the magnetization fixed layer MP1 is a magnetization fixed in the +Z axis direction; and the magnetization MG2 of the magnetic recording layer MR1 is a magnetization pointing in the −Z axis direction. Whereas, the following state is referred to as data “O”: the magnetization MG1 of the magnetization fixed layer MP1 is a magnetization fixed in the +Z axis direction; and the magnetization MG2 of the magnetic recording layer MR1 is a magnetization pointing in the +Z axis direction. Incidentally, the correspondence between the magnetization direction and the value of data may be reversed.

When data “1” is written into the magnetic memory element MM1 with data “0” written therein, the write current is passed, for example, as indicated with a current path CP1, from the cap layer CL1 via the magnetic recording layer MR1 in the direction of the base layer BF1. At this step, into the magnetic recording layer MR1, electrons having spin torques in both positive and reverse directions are injected. However, of them, electrons having a unidirectional spin torque are repelled by the magnetic recording layer MR1. As a result, the magnetization MG2 of the magnetic recording layer MR1 is reversed vertically.

When data “0” is written into the magnetic memory element MM2 with data “1” written therein, the write current is passed, for example, as indicated with the current path CP1, from the base layer BF1 via the magnetic recording layer MR1 in the direction of the magnetization fixed layer MP1. At this step, into the magnetic recording layer MR1, there are injected electrons having a unidirectional spin torque which have passed through the magnetization fixed layer MP1 of the spin torques in both positive and reverse directions. As a result, the magnetization MG2 of the magnetic recording layer MR1 is reversed vertically.

Namely, the write current flows between the conductive film CF1 and the conductive film CF2 via the ferromagnetic film FM1. This results in a change in magnetization MG2 of the ferromagnetic film FM1.

Incidentally, the read operation of data of the magnetic memory element MM2 can be performed in the same manner as the read operation of the magnetic memory element MM1 of First Embodiment. Namely, for example, as indicated with the current path CP2, the read current is passed between the magnetization fixed layer MP1 and the base layer BF1. Thus, the resistance value is detected by the current value flowing therebetween.

<First Modified Example of Magnetic Memory Element>

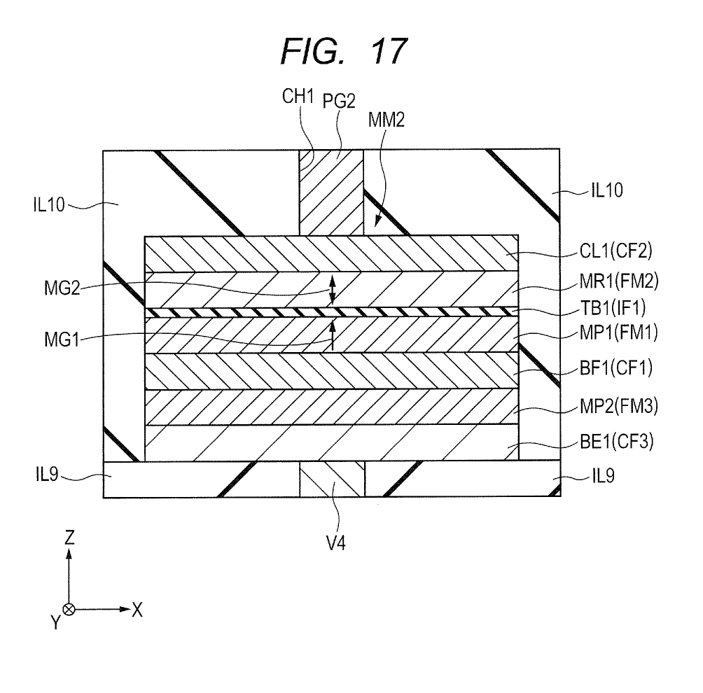

In the example shown in FIG. 14, over the magnetic recording layer MR1, the magnetization fixed layer MP1 is formed via the tunnel barrier layer TB1. However, over the magnetization fixed layer MP1, the magnetic recording layer MR1 may be formed via the tunnel barrier layer TB1. Such an example is shown in FIG. 17. FIG. 17 is a cross sectional view showing a magnetic memory element of a semiconductor device of a first modified example of Second Embodiment.

As shown in FIG. 17, in the present first modified example, the magnetic memory element MM2 has a base layer BF1, a magnetic recording layer MR1, a tunnel barrier layer TB1, a magnetization fixed layer MP1, a cap layer CL1, and a bottom electrode layer BE1. Over the base layer BF1, there is formed the magnetization fixed layer MP1. Over the magnetization fixed layer MP1, there is formed the tunnel barrier layer TB1. Over the tunnel barrier layer TB1, there is formed the magnetic recording layer MR1. Over the magnetic recording layer MR1, there is formed the cap layer CL1. The magnetic recording layer MR1, the tunnel barrier layer TB1, and the magnetization fixed layer MP1 form a MTJ. Namely, the magnetic recording layer MR1, the tunnel barrier layer TB1, and the magnetization fixed layer MP1 form a tunnel magnetoresistive effect element.

On the other hand, in the present first modified example, the magnetic recording layer MR1 is formed of a ferromagnetic film FM2, and the magnetization fixed layer MP1 is formed of a ferromagnetic film FM1. Namely, over the conductive film CF1, there is formed the ferromagnetic film FM1. Over the ferromagnetic film FM1, there is formed an insulation film IF1. Over the insulation film IF1, there is formed the ferromagnetic film FM2. Therefore, the ferromagnetic film FM1 has a magnetization MG1 fixed in the +Z axis direction. On the other hand, the ferromagnetic film FM2 has a magnetization MG2 reversible between the +Z axis direction and the −Z axis direction.

Further, in the present first modified example, the magnetic memory element MM2 has a magnetization fixed layer MP2. Whereas, under the base layer BF1, there is formed a magnetization fixed layer MP2. Under the magnetization fixed layer MP2, there is formed a bottom electrode layer BE1. The magnetization fixed layer MP2 is magnetically coupled with the magnetization fixed layer MP1 via the base layer BF1 as a non-magnetic conductive layer. Then, the magnetization fixed layer MP1, the base layer BF1, and the magnetization fixed layer MP2 form a data reference layer.

The magnetization fixed layer MP2 includes a ferromagnetic film FM3. The ferromagnetic film FM3 has a perpendicular magnetic anisotropy. Namely, the direction of magnetization of the ferromagnetic film FM3 is a direction in parallel with the film thickness direction of the ferromagnetic film FM3.

The ferromagnetic film FM3 is formed of a metal, or an alloy of two or more metals selected from, for example, Fe (iron), Co (cobalt), and Ni (nickel). Alternatively, the ferromagnetic film may contain therein Pt (platinum) or Pd (palladium). This can stabilize the perpendicular magnetic anisotropy.

Further, to the ferromagnetic film FM3, are added various elements such as B, C, N, O, Al, Si, P, Ti, V, Cr, Mn, Cu, Zn, Zr, Nb, Mo, Tc, Ru, Rh, Ag, Hf, Ta, W, Re, Os, Ir, Au, or Sm. This can adjust the magnetic characteristics.

As the ferromagnetic film FM3, specifically, there can be used an alloy film formed of a material such as Co, Co—Pt, Co—Pd, Co—Cr, Co—Pt—Cr, Co—Cr—Ta, Co—Cr—B, Co—Cr—Pt—B, or Co—Cr—Ta—B. Alternatively, there can be used an alloy film formed of a material such as Co—V, Co—Mo, Co—W, Co—Ti, Co—Ru, Co—Rh, Fe—Pt, Fe—Pd, Fe—Co—Pt, Fe—Co—Pd, or Sm—Co.

Alternatively, the ferromagnetic film FM3 can be configured as a lamination film of films formed of the materials described above. For example, there may be used a lamination film of two or more metal films selected from Fe, Co, and Ni. Specifically, as the ferromagnetic film, there can be used a lamination film such as Co/Ni, Co/Pd, Co/Pt, or Fe/Au.

The ferromagnetic films FM1 and FM2 in the present first modified example can also be configured the same as the ferromagnetic films FM1 and FM2 of First Embodiment, respectively. Therefore, also in the present first modified example, as with First Embodiment, each of the ferromagnetic films FM1 and FM2 contains Co (cobalt), Fe (iron), and B (boron). When such a ferromagnetic film containing Co, Fe, and B has a body-centered cubic structure, the MR ratio of the tunnel magnetoresistive effect element can be increased.

The conductive film CF1 in the present first modified example can also be configured the same as the conductive film CF1 of First Embodiment. Therefore, for example, preferably, the conductive film CF1 is formed of a metal nitride, or a metal in an amorphous state. As a result, the conductive film CF1 becomes less likely to be crystallized. For this reason, the ferromagnetic film FM1 formed over the conductive film CF1 becomes less susceptible to the crystal structure of the conductive film CF1. On the other hand, the ferromagnetic film FM1 becomes more susceptible to the crystal structure of the insulation film IF1 formed over the ferromagnetic film FM1, and containing MgO.

<Second Modified Example of Magnetic Memory Element>

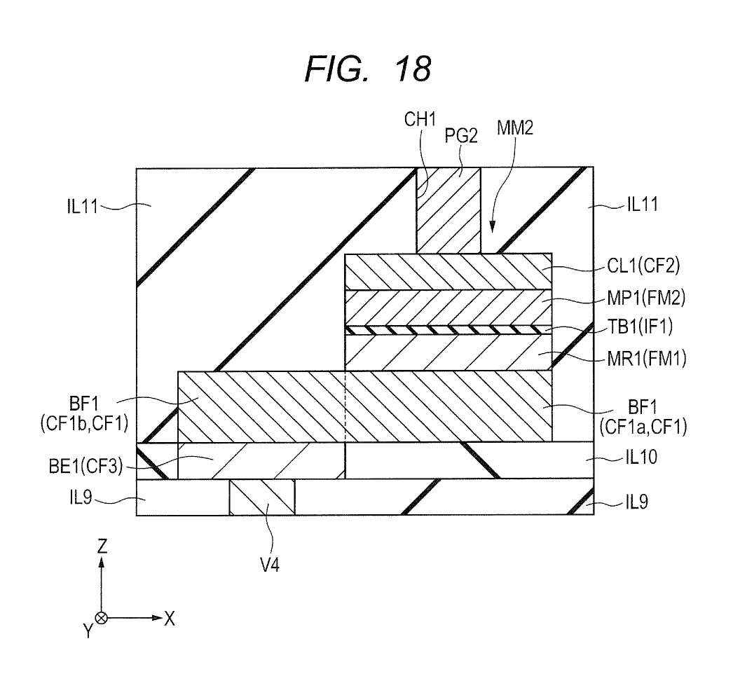

In the example shown in FIG. 14, the magnetic recording layer MR1 is formed over the entire top surface of the base layer BF1. However, the magnetic recording layer MR1 is formed over a part of the top surface of the base layer BF1. The magnetic recording layer MR1 may be formed in such a manner as to be internally included in the base layer BF1 in a plan view. Such an example is shown in FIG. 18. FIG. 18 is a cross sectional view showing a magnetic memory element of a semiconductor device of a second modified example of Second Embodiment.

As shown in FIG. 18, the base layer BF1, namely, the conductive film CF1 includes a region CF1a and a region CF1b adjacent to each other in a plan view. Namely, the conductive film CF1 includes the region CF1a, and the region CF1b situated on one side of the region CF1a in a plan view. In this case, the magnetic recording layer MR1, namely, the ferromagnetic film FM1 is formed over the region CF1a of the conductive film CF1. Further, the bottom electrode layer BE1, namely, the conductive film CF3 is formed under the region CF1b of the conductive film CF1.

As a result, ad described by reference to FIG. 25 described later, when the conductive film CF2, the ferromagnetic film FM2, the insulation film IF1, and the ferromagnetic film FM1 are etched and patterned, the conductive film CF1 can be allowed to function as an etching stopper. For this reason, by overetching the conductive film CF2, the ferromagnetic film FM2, the insulation film IF1, and the ferromagnetic film FM1, it is possible to remove the deposit deposited at, for example, the sidewall of the insulation film IF1. Therefore, the deposit deposited at the sidewall of the insulation film IF1, or the like can prevent a short circuit between the magnetization fixed layer MP1 and the magnetic recording layer MR1.

Further, as shown in FIG. 18, when the bottom electrode layer BE1 is provided under the region CF1b of the base layer BF, the base layer BF1 can be used as a wire. In such a case, by increasing the film thickness of the conductive film CF1 included in the base layer BF1, it is possible to reduce the electric resistance of the base layer BF1 as a wire. This can reduce the heat value generated by passing a current for write of data and read of data.

As described by reference to FIG. 25 described later, even when the film thickness of the conductive film CF1 is increased to about 20 nm by using a conductive film formed of TaN as the conductive film CF1, it is possible to sufficiently ensure the coercive force of the perpendicular magnetization in the ferromagnetic film FM1 included in the magnetic recording layer MR1. For this reason, the MR ratio of the magnetic memory element MM2 can be increased.

<Method for Manufacturing a Semiconductor Device>

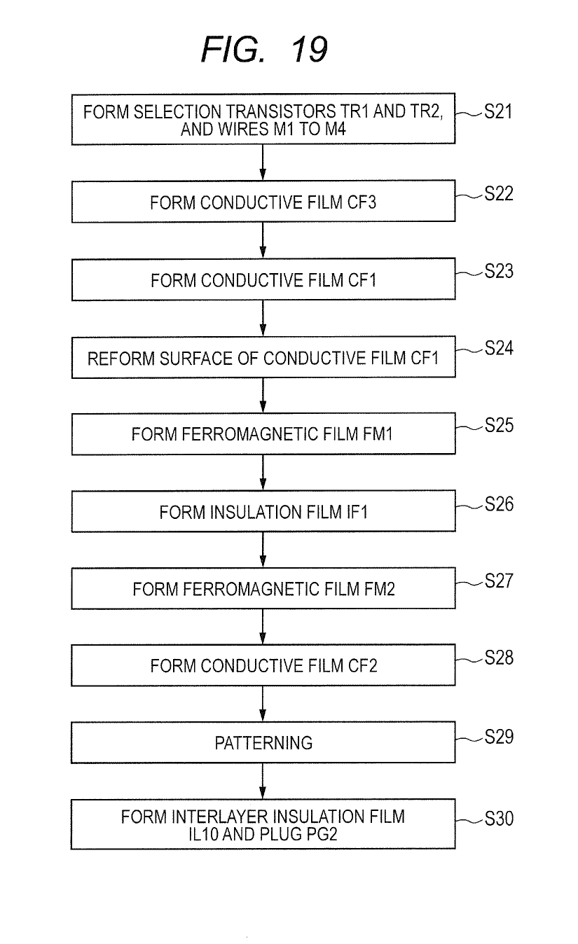

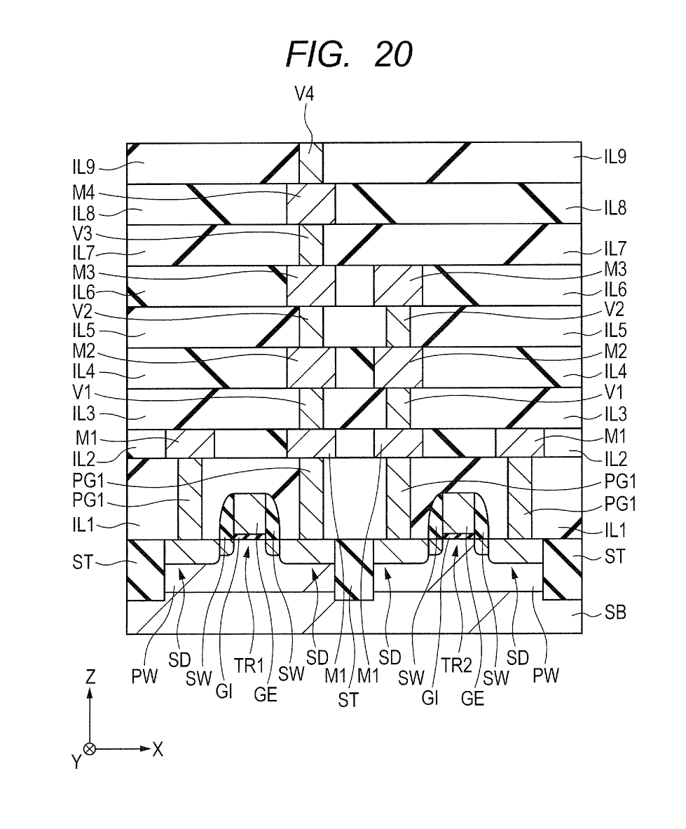

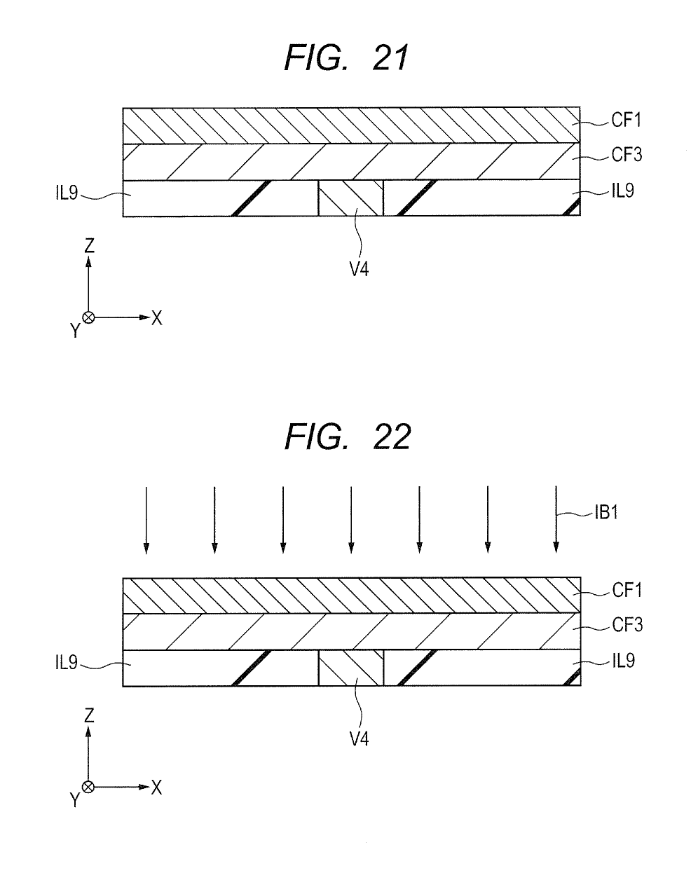

Then, with reference to FIGS. 19 to 24, a description will be given to a method for manufacturing the semiconductor device of the present Second Embodiment. FIG. 19 is a process flowchart showing some of manufacturing steps of the semiconductor device of Second Embodiment. FIGS. 20 to 24 are each a cross sectional view showing the semiconductor device of Second Embodiment during a manufacturing step. Of FIGS. 20 to 24, FIG. 20 is a cross sectional view showing the formation step of the selection transistors TR1 and TR2, and the wires M1 to M4. FIGS. 21 to 24 are each a cross sectional view showing a formation step of the magnetic memory element MM2.

First, the same step as Step S11 of FIG. 5 is performed. Thus, as shown in FIG. 20, at the main surface of the semiconductor substrate SB, there are formed two selection transistors TR1 and TR2. Further, above the selection transistors TR1 and TR2, there are formed wires M1 to M4 (Step S21 of FIG. 19).

Then, over the interlayer insulation film IL9 including the via part V4 embedded therein, there is formed a magnetic memory element MM2.

First, as shown in FIG. 21, there is formed a conductive film CF3 (Step S22 of FIG. 19). In the Step S22, over the interlayer insulation film IL9 including the via part V4 embedded therein, there is formed a conductive film CF3 for the bottom electrode layer BE1. As the conductive film CF3, there can be used a conductive film of, for example, Ta (tantalum), TaN (tantalum nitride), Pt (platinum), Ru (ruthenium), Ti (titanium), or TiN (titanium nitride). Alternatively, as the conductive film CF3, there may be used a lamination film of Ta, Ru, and Ta.

Then, the same step as Step S13 of FIG. 5 is performed. As a result, as shown in FIG. 21, over the conductive film CF3, there is formed a conductive film CF1 (Step S23 of FIG. 19).

Then, the same step as Step S14 of FIG. 5 is performed. As a result, as shown in FIG. 22, the surface of the conductive film CF1 is reformed (Step S24 of FIG. 19). Especially, in the second reforming step, the surface of the conductive film CF1 is etched by an ion beam IB1 of, for example, Ar⁺ (argon ion). At this step, the same step as the first modified example of Step S14 may be performed as a first modified example of Step S24. Alternatively, the same step as the second modified example of Step S14 may be performed as a second modified example of Step S24.

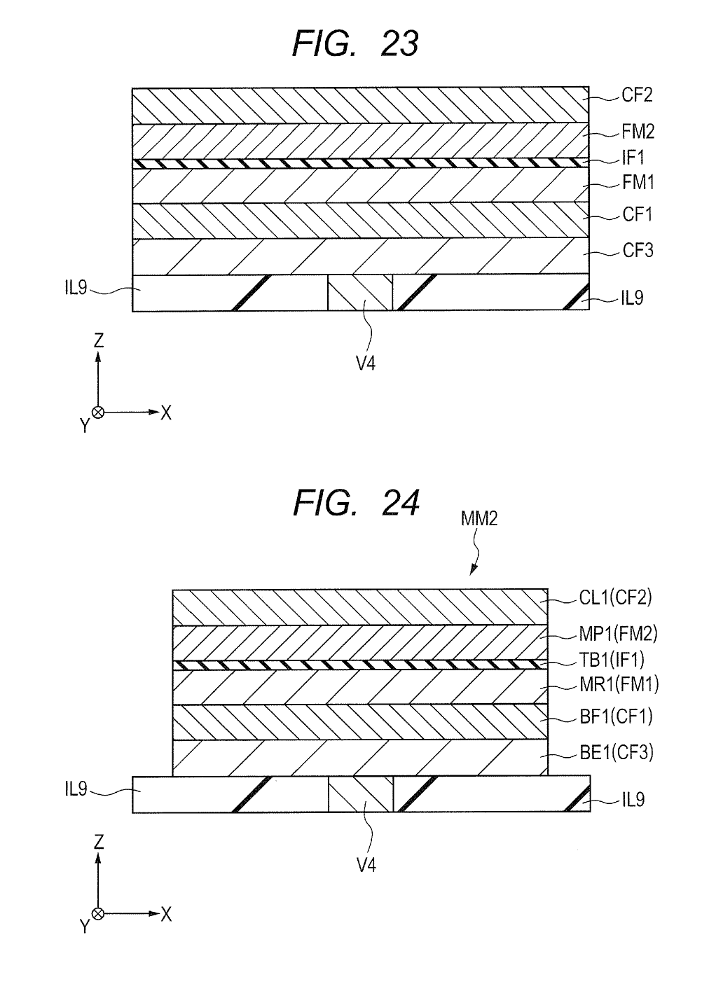

Then, the same step as Step S15 of FIG. 5 is performed. As a result, as shown in FIG. 23, over the conductive film CF1, there is formed a ferromagnetic film FM1 (Step S25 of FIG. 19). Then, the same step as Step S16 of FIG. 5 is performed. As a result, as shown in FIG. 23, over the ferromagnetic film FM1, there is formed an insulation film IF1 (Step S26 of FIG. 19). Then, the same step as Step S17 of FIG. 5 is performed. As a result, as shown in FIG. 23, over the insulation film IF1, there is formed a ferromagnetic film FM2 (Step S27 of FIG. 19). Then, the same step as Step S18 of FIG. 5 is performed. As a result, as shown in FIG. 23, over the ferromagnetic film FM2, there is formed a conductive film CF2 (Step S28 of FIG. 19).

Then, the same step as Step S19 of FIG. 5 is performed. As a result, as shown in FIG. 24, there are patterned the conductive film CF2, the ferromagnetic film FM2, the insulation film IF1, the ferromagnetic film FM1, the conductive film CF1, and the conductive film CF3 (Step S29 of FIG. 19). At this step, there are formed a bottom electrode layer BE1 formed of the patterned conductive film CF3, a base layer BF1 formed of the conductive film CF1 at a portion thereof left over the bottom electrode layer BE1, and a magnetic recording layer MR1 formed of the ferromagnetic film FM1 at a portion thereof left over the base layer BF1. Further, there are formed a tunnel barrier layer TB1 formed of the insulation film IF1 at a portion thereof left over the magnetic recording layer MR1, a magnetization fixed layer MP1 formed of the ferromagnetic film FM2 at a portion thereof left over the tunnel barrier layer TB1, and a cap layer CL1 formed of the conductive film CF2 at a portion thereof left over the magnetization fixed layer MP1. Furthermore, the magnetic recording layer MR1, the tunnel barrier layer TB1, and the magnetization fixed layer MP1 form a magnetic memory element MM2.

Then, the same step as Step S20 of FIG. 5 is performed. As a result, as shown in FIG. 14, there are formed an interlayer insulation film IL10 and a plug PG2 (Step S30 of FIG. 19).

Then, over the interlayer insulation film IL10, there are formed wires (not shown). By the steps up to this point, as shown in FIG. 14, there can be formed the selection transistors TR1 and TR2, the wires M1 to M4, and the magnetic memory element MM2. Incidentally, the manufacturing steps of the semiconductor device of the present Second Embodiment also have a step of performing a heat treatment for crystallization of the ferromagnetic film FM1 and the insulation film IF1 after the formation of the insulation film IF1 as with the manufacturing steps of the semiconductor device of First Embodiment.

<Regarding the Relationship Between the Material and the Composition Ratio of a Conductive Film, and the MR Ratio>

Also in the present Second Embodiment, the relationship between the material and the composition ratio of the conductive film CF1 and the MR ratio can be set the same as the relationship between the material and the composition ratio of the conductive film CF1 and the MR ratio described by reference to FIGS. 12 and 13 in First Embodiment.

<Regarding the Relationship Between the Film Thickness of the Base Layer and the Perpendicular Magnetization of the Magnetic Recording Layer>

FIG. 25 is a graph showing the relationship between the film thickness of the base layer and the perpendicular magnetization of the magnetic recording layer. The horizontal axis of the graph shown in FIG. 25 denotes the film thickness of the conductive film CF1 included in the base layer BF1; and the vertical axis of the graph shown in FIG. 25 denotes the coercive force of the perpendicular magnetization of the ferromagnetic film FM1 included in the magnetic recording layer MR1. Further, in FIG. 25, the case where the conductive film CF1 formed of Ta is used is shown as Comparative Example 3; and the case where the conductive film CF1 formed of TaN is used is shown as Example 3.

As shown in FIG. 25, in Comparative Example 3, when the film thickness of the conductive film CF1 falls within the range of 0.8 to 1.5 nm, the ferromagnetic film FM1 shows the perpendicular magnetization. On the other hand, in Example 3, when the range of the film thickness of the conductive film CF1 falls within the range of 1 to 20 nm, the ferromagnetic film FM1 shows the perpendicular magnetization. Namely, in Example 3, even when the conductive film CF1 has a film thickness within a wider range than in Comparative Example 3, the ferromagnetic film FM1 has the perpendicular magnetization. Accordingly, in the case where a ferromagnetic film FM1 formed of a CoFeB film is formed over the conductive film CF1 formed of TaN, even when the conductive film CF1 has a film thickness in a wider range as compared with the case where a ferromagnetic film FM1 formed of a CoFeB film is formed over the conductive film CF1 formed of Ta, the ferromagnetic film FM1 has a perpendicular magnetization.

Therefore, in a second modified example of Second Embodiment described by reference to FIG. 18, when the conductive film CF1 is formed of a metal nitride such as TaN, the film thickness of the conductive film CF1 can be set at, for example, about 5 to 20 nm, larger than when the conductive film CF1 is formed of a metal such as Ta. As a result, when, in Step S29 of FIG. 19, the conductive film CF2, the ferromagnetic film FM2, the insulation film IF1, and the ferromagnetic film FM1 are etched and patterned, the conductive film CF1 can be allowed to function as an etching stopper. For this reason, by overetching the conductive film CF2, the ferromagnetic film FM2, the insulation film IF1, and the ferromagnetic film FM1, it is possible to remove the deposit deposited at, for example, the sidewall of the insulation film IF1. Therefore, the deposit deposited at the sidewall of the insulation film IF1, or the like can prevent a short circuit between the magnetization fixed layer MP1 and the magnetic recording layer MR1.

Further, as shown in FIG. 18, when the bottom electrode layer BE1 is provided under the region CF1b of the base layer BF1, the base layer BF1 can be used as a wire. In such a case, by increasing the film thickness of the conductive film CF1 included in the base layer BF1, it is possible to reduce the electric resistance of the base layer BF1 as a wire. This can reduce the heat value generated by passing a current for write of data and read of data.

Even when the film thickness of the conductive film CF1 is increased to about 20 nm by using a conductive film formed of TaN as the conductive film CF1 included in the base layer BF1, it is possible to sufficiently ensure the coercive force of the perpendicular magnetization in the ferromagnetic film FM1 included in the magnetic recording layer MR1. For this reason, the MR ratio of the magnetic memory element MM2 can be increased.

<Main Features and Effects of the Present Embodiment>

The semiconductor device of the present Second Embodiment has, as with the semiconductor device of First Embodiment, a conductive film CF1 formed above a semiconductor substrate, a ferromagnetic film FM1 formed over the conductive film CF1, an insulation film IF1 formed over the ferromagnetic film FM1, and a ferromagnetic film FM2 formed over the insulation film IF1. The ferromagnetic film FM1, the insulation film IF1, and the ferromagnetic film FM2 form a magnetic memory element MM2 as a tunnel magnetoresistive effect element. The conductive film CF1 is formed of a metal nitride, or formed of a metal containing Xe. The ferromagnetic film FM1 contains Co, Fe, and B, and the insulation film IF1 contains MgO.

As a result, also in the semiconductor device of the present Second Embodiment, as with the semiconductor device of First Embodiment, the ferromagnetic film FM1 can have a body-centered cubic structure. This can increase the MR ratio of the tunnel magnetoresistive effect element formed of the ferromagnetic film FM1, the insulation film IF1, and the ferromagnetic film FM2. For this reason, it is possible to improve the performances of a semiconductor device including the magnetic memory element MM2.

On the other hand, in the semiconductor device of the present Second Embodiment, when a write current is passed between the cap layer CL1 and the bottom electrode layer BE1, a larger current is not required to be passed through the magnetic recording layer MR1 of the magnetic recording layer MR1 and the base layer BF1. For this reason, as compared with First Embodiment, the film thickness of the base layer BF1 can be set larger. In such a case, when the conductive film CF2, the ferromagnetic film FM2, the insulation film IF1, and the ferromagnetic film FM1 are etched, the conductive film CF1 can be allowed to function as an etching stopper. For this reason, by overetching the conductive film CF2, the ferromagnetic film FM2, the insulation film IF1, and the ferromagnetic film FM1, it is possible to remove the deposit deposited at, for example, the sidewall of the insulation film IF1. Therefore, the deposit deposited at the sidewall of the insulation film IF1, or the like can prevent a short circuit between the magnetization fixed layer MP1 and the magnetic recording layer MR1.

### Third Embodiment

In First Embodiment, a description has been given to the applied example to the domain wall displacement type MRAM. In contrast, in Third Embodiment, a description will be given to an applied example to a MRAM (SHE-MRAM) using a Spin Hall Effect: SHE.

Incidentally, the portion of the semiconductor device below the magnetic memory element MM3 in the present Third Embodiment can be configured the same as the portion of the semiconductor device below the magnetic memory element MM1 in First Embodiment described by reference to FIG. 2. Whereas, the selection transistors in the present Third Embodiment can also be configured the same as the selection transistors in First Embodiment described by reference to FIG. 2.

<Magnetic Memory Element>

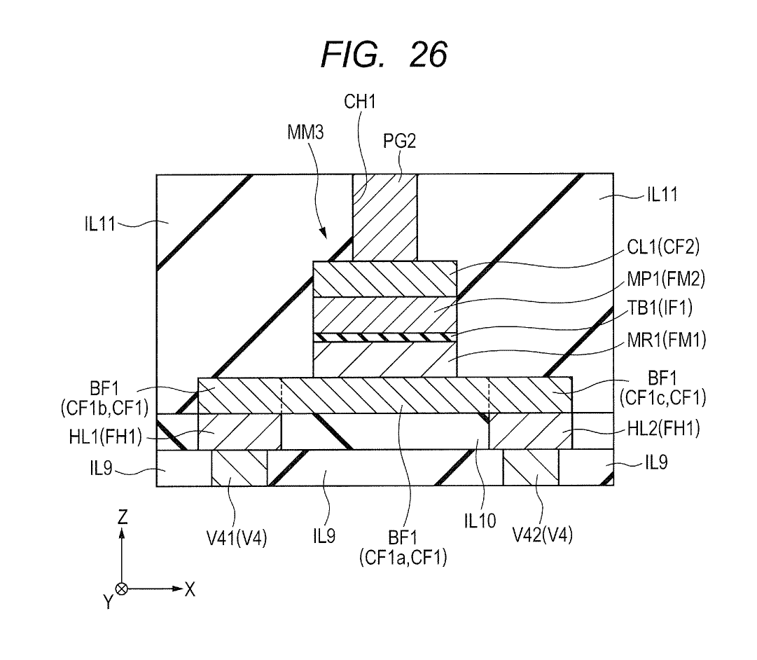

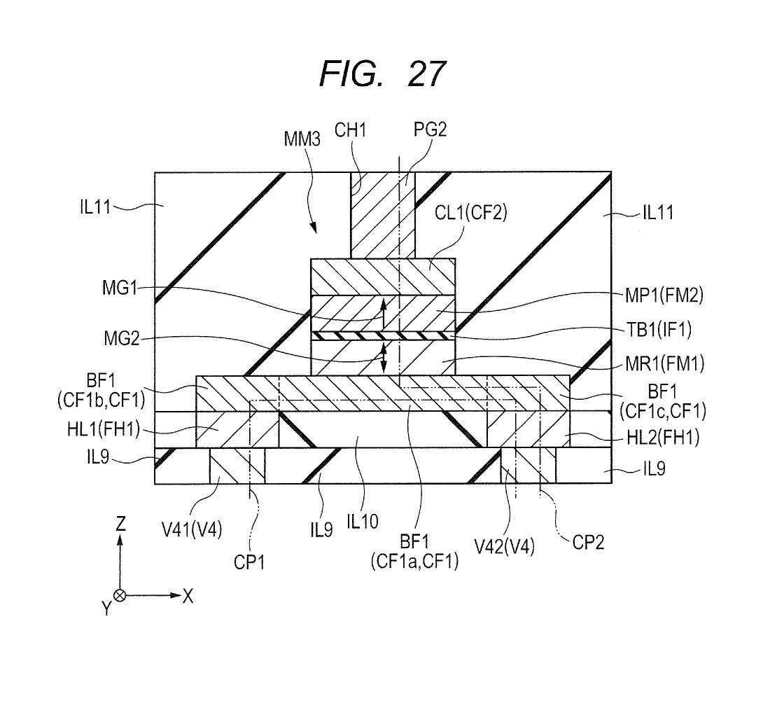

FIG. 26 is a cross sectional view showing a magnetic memory element of the semiconductor device of Third Embodiment. FIG. 27 is a view showing the direction of magnetization of each ferromagnetic film in the magnetic memory element of Third Embodiment.

As shown in FIG. 26, a magnetic memory element MM3 has a base layer BF1, a magnetic recording layer MR1, a tunnel barrier layer TB1, a magnetization fixed layer MP1, and a cap layer CL1. Above the semiconductor substrate SB, there is formed the base layer BF1. Over the base layer BF1, there is formed the magnetic recording layer MR1. Over the magnetic recording layer MR1, there is formed the tunnel barrier layer TB1. Over the tunnel barrier layer TB1, there is formed the magnetization fixed layer MP1. Over the magnetization fixed layer MP1, there is formed the cap layer CL1.

Under a portion of the base layer BF1 situated on one side of the central part thereof, there is formed a magnetization fixed layer HL1. Under a portion of the base layer BF1 situated on the other side of the central part thereof, there is formed a magnetization fixed layer HL2. The magnetic recording layer MR1, the tunnel barrier layer TB1, and the magnetization fixed layer MP1 form a MTJ. Namely, the magnetic recording layer MR1, the tunnel barrier layer TB1, and the magnetization fixed layer MP1 form a tunnel magnetoresistive effect element.

The magnetic recording layer MR1 is formed of a ferromagnetic film FM1. The magnetic recording layer MR1 forms a data storage layer. On the other hand, the magnetization fixed layer MP1 is formed of a ferromagnetic film FM2. The magnetization fixed layer MP1 forms a data reference layer. Alternatively, the ferromagnetic film FM2 may be formed of a plurality of ferromagnetic layers.

Each of the ferromagnetic films FM1 and FM2 has a perpendicular magnetic anisotropy. Namely, respective directions of magnetization of the ferromagnetic films FM1 and FM2 are directions in parallel with respective film thickness directions of the ferromagnetic films FM1 and FM2, and are directions perpendicular to respective top surfaces of the ferromagnetic films FM1 and FM2, respectively.

The ferromagnetic films FM1 and FM2 in the present Third Embodiment can also be configured the same as the ferromagnetic films FM1 and FM2 of First Embodiment, respectively. Therefore, also in the present Third Embodiment, as with First Embodiment, each of the ferromagnetic films FM1 and FM2 contains Co (cobalt), Fe (iron), and B (boron). When such a ferromagnetic film containing Co, Fe, and B has a body-centered cubic structure, the MR ratio of the tunnel magnetoresistive effect element can be increased.

Incidentally, when the magnetization fixed layer MP1 includes other ferromagnetic films than the ferromagnetic film FM2, of the ferromagnetic films included in the magnetization fixed layer MP1, other ferromagnetic films than the ferromagnetic film FM2 can be configured the same as those in First Embodiment.

The tunnel barrier layer TB1 is formed of an insulation film IF1. The insulation film IF1 in the present Third Embodiment can also be configured the same as the insulation film IF1 of First Embodiment. Preferably, the insulation film IF1 contains MgO (magnesium oxide).

Also in the present Third Embodiment, as with First Embodiment, above the semiconductor substrate SB, there is formed a conductive film CF1. Over the conductive film CF1, there is formed a ferromagnetic film FM1. Over the ferromagnetic film FM1, there is formed an insulation film IF1. Over the insulation film IF1, there is formed a ferromagnetic film FM2. Then, the ferromagnetic film FM1, the insulation film IF1, and the ferromagnetic film FM2 form a tunnel magnetoresistive effect element.

Herein, as shown in FIG. 26, in a plan view, the central part of the base layer BF1, namely, the conductive film CF1 is referred to as a region CF1a. Whereas, in a plan view, the portion of the conductive film CF1 situated on one side of the region CF1a is referred to as a region CF1b. In a plan view, a portion of the conductive film CF1 situated opposite to the region CF1b across the region CF1a is referred to as a region CF1c. Namely, the conductive film CF1 includes the region CF1a, the region CF1b, and the region CF1c.

At this step, the magnetic recording layer MR1, namely, the ferromagnetic film FM1 is formed over the region CF1a. Whereas, the magnetization fixed layer HL1 is formed under the region CF1b of the conductive film CF1. The magnetization fixed layer HL2 is formed under the region CF1c of the conductive film CF1.

The magnetic recording layer MR1 in the present Third Embodiment is different from the ferromagnetic film in First Embodiment in being formed over the region CF1a, but being not formed over the region CF1b, and over the region CF1c as described previously. Namely, the semiconductor device of the present Third Embodiment is not a domain wall displacement type MRAM. For this reason, in a plan view, the ferromagnetic film FM1 is not required to be formed over the magnetization fixed layer HL1, and over the magnetization fixed layer HL2.

On the other hand, the conductive film CF1 included in the base layer BF1 in the present Third Embodiment includes, in addition to the region CF1a which is a portion overlapping the magnetic recording layer MR1 in a plan view, the region CF1b which is a portion overlapping the magnetization fixed layer HL1 in a plan view, and the region CF1c which is a portion overlapping the magnetization fixed layer HL2 in a plan view. Namely, in the present Third Embodiment, the conductive film CF1 is formed integrally from the region CF1b which is a portion overlapping the magnetization fixed layer HL1 in a plan view, through the region CF1a which is a portion overlapping the magnetic recording layer MR1 in a plan view, to the region CF1c which is a portion overlapping the magnetization fixed layer HL2 in a plan view. By changing the direction of the current passed through such a conductive film CF1 included in the base layer BF1, it is possible to reverse the direction of the spin flow generated by the spin hole effect in the conductive film CF1 included in the base layer BF1. For this reason, it is possible to vertically reversing the perpendicular magnetization of the ferromagnetic film FM1 included in the magnetic recording layer MR1.

Whereas, in the present Third Embodiment, when the conductive film CF2, the ferromagnetic film FM2, the insulation film IF1, and the ferromagnetic film FM1 are etched and patterned, the conductive film CF1 having a film thickness of, for example, about 5 to 20 nm can be allowed to function as an etching stopper. For this reason, by overetching the conductive film CF2, the ferromagnetic film FM2, the insulation film IF1, and the ferromagnetic film FM1, it is possible to remove the deposit deposited at, for example, the sidewall of the insulation film IF1. Therefore, the deposit deposited at the sidewall of the insulation film IF1, or the like can prevent a short circuit between the magnetization fixed layer MP1 and the magnetic recording layer MR1.

<Operation of Magnetic Memory Element>

As shown in FIG. 27, for example, the magnetization fixed layer MP1, namely, the ferromagnetic film FM2 has a magnetization MG1 fixed in the +Z axis direction. On the other hand, the magnetic recording layer MR1, namely, the ferromagnetic film FM1 has a magnetization MG2 reversible between the +Z axis direction and the −Z axis direction.

Then, a description will be given to the write operation of data in the magnetic memory element MM3. Also in the present Third Embodiment, as with First Embodiment, the following state is referred to as data “1”: the magnetization MG1 of the magnetization fixed layer MP1 is a magnetization fixed in the +Z axis direction; and the magnetization MG2 of the magnetic recording layer MR1 is a magnetization pointing in the −Z axis direction. Whereas, the following state is referred to as data “0”: the magnetization MG1 of the magnetization fixed layer MP1 is a magnetization fixed in the +Z axis direction; and the magnetization MG2 of the magnetic recording layer MR1 is a magnetization pointing in the +Z axis direction. Incidentally, the correspondence between the magnetization direction and the value of data may be reversed.

When data “1” is written into the magnetic memory element MM3 with data “0” written therein, the write current is passed, for example, as indicated with a current path CP1, from the magnetization fixed layer HL1 via the base layer BF1 in the direction of the magnetization fixed layer HL2. A spin hole effect generates a spin flow in a direction perpendicular to the write current. Then, the generated spin flow vertically reverses the magnetization MG2 of the magnetic recording layer MR1.

When data “0” is written into the magnetic memory element MM3 with data “1” written therein, the write current is passed, for example, as indicated with a current path CP1, from the magnetization fixed layer HL2 via the base layer BF1 in the direction of the magnetization fixed layer HL1. A spin hole effect generates a spin flow in a direction perpendicular to the write current. Then, the generated spin flow vertically reverses the magnetization MG2 of the magnetic recording layer MR1.

Incidentally, even when the base layer BF1 is not applied with a magnetic field, the spin hole effect can be generated. Therefore, the magnetization fixed layers HL1 and HL2 are not required to be provided; the region CF1b of the conductive film CF1 may be directly coupled with the via part V41; and the region CF1c of the conductive film CF1 may be directly coupled with the via part V42. At this step, a write current flows between the region CF1b of the conductive film CF1 and the region CF1c of the conductive film CF1 via the region CF1a of the conductive film CF1. This results in a change in direction of the magnetization MG2 of the ferromagnetic film FM1.

Further, the read operation of data of the magnetic memory element MM3 can be performed in the same manner as the read operation of the magnetic memory element MM1 of First Embodiment. Namely, for example, as indicated with the current path CP2, the read current is passed between the magnetization fixed layer MP1 and the base layer BF1. Thus, the resistance value is detected by the current value flowing therebetween.

<Method for Manufacturing a Semiconductor Device>

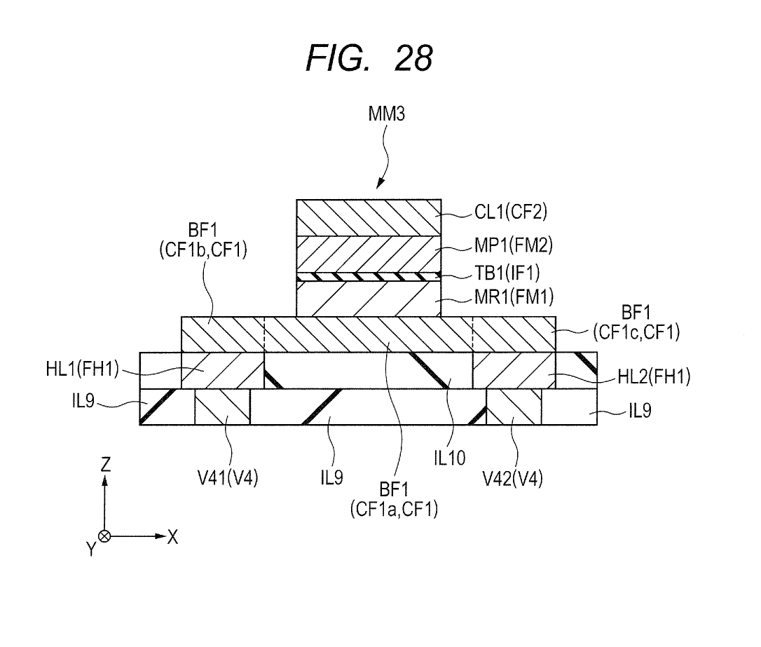

Then, with reference to FIG. 28, a description will be given to a method for manufacturing a semiconductor device of the present Third Embodiment. FIG. 28 is a cross sectional view showing a semiconductor device of Third Embodiment during a manufacturing step. FIG. 28 is a cross sectional view showing a formation step of a magnetic memory element MM3.

First, the same step as Step S11 of FIG. 5 is performed. As a result, as shown in FIG. 6, at the main surface of the semiconductor substrate SB, there are formed two selection transistors TR1 and TR2. Further, above the selection transistors TR1 and TR2, there are formed wires M1 to M4.

Then, over an interlayer insulation film IL9 including via parts V41 and V42 as via parts V4 embedded therein, there is formed a magnetic memory element MM3.

First, the same step as Step S12 of FIG. 5 is performed. As a result, as shown in FIG. 7, over the interlayer insulation film IL9 including the via parts V41 and V42 as the via parts V4 embedded therein, there are formed magnetization fixed layers HL1 and HL2, and an interlayer insulation film IL10.

Incidentally, as described previously, in the present Third Embodiment, the magnetization fixed layers HL1 and HL2 are not required to be formed. In that case, the interlayer insulation film IL10 is also not required to be formed.

Then, the same step as Step S13 of FIG. 5 is performed. As a result, as shown in FIG. 8, over the interlayer insulation film IL10 including the magnetization fixed layers HL1 and HL2 embedded therein, there is formed a conductive film CF1.

Then, the same step as Step S14 of FIG. 5 is performed. As a result, as shown in FIG. 9, the surface of the conductive film CF1 is reformed. At this step, the same step as the first modified example of Step S14, or the same step as the second modified example of Step S14 may be performed in place of the step of Step S14.

Then, the same step as Step S15 of FIG. 5 is performed. As a result, as shown in FIG. 10, over the conductive film CF1, there is formed a ferromagnetic film FM1. Then, the same step as Step S16 of FIG. 5 is performed. As a result, as shown in FIG. 10, over the ferromagnetic film FM1, there is formed an insulation film IF1. Then, the same step as Step S17 of FIG. 5 is performed. As a result, as shown in FIG. 10, over the insulation film IF1, there is formed a ferromagnetic film FM2. Then, the same step as Step S18 of FIG. 5 is performed. As a result, as shown in FIG. 10, over the ferromagnetic film FM1, there is formed a conductive film CF2.

Then, the step corresponding to Step S19 of FIG. 5 is performed. As a result, as shown in FIG. 10, there are patterned the conductive film CF2, the ferromagnetic film FM2, the insulation film IF1, the ferromagnetic film FM1, and the conductive film CF1.

In the step corresponding to the Step S19, first, over the conductive film CF2, an insulation film such as a silicon oxide film (not shown) is formed by a CVD method. Thus, the insulation film is patterned. As a result, in a plan view, in a region of the conductive film CF1 in which the regions CF1a, CF1b, and CF1c are left, there is left the insulation film. Then, using the left portion of the insulation film (not shown) as a mask, there are etched the conductive film CF2, the ferromagnetic film FM2, the insulation film IF1, the ferromagnetic film FM1, and the conductive film CF1.

As a result, in a region of the conductive film CF1 in which the regions CF1a, CF1b, and CF1c are left, there are left the conductive film CF2, the ferromagnetic film FM2, the insulation film IF1, the ferromagnetic film FM1, and the conductive film CF1. At this step, as shown in FIG. 28, there is formed the base layer BF1 formed of the region CF1a of the conductive film CF1, the region CF1b of the conductive film CF1, and the region CF1c of the conductive film CF1. In other words, of the conductive film CF1, there are left the region CF1a, the region CF1b situated on one side of the region CF1a, and the region CF1c situated opposite to the region CF1b across the region CF1a.

Then, using a hard mask (not shown) formed of the insulation film at a portion thereof formed over the conductive film CF2, and left over the region CF1a as a mask, etching is performed. As a result, there are left the conductive film CF2, the ferromagnetic film FM2, the insulation film IF1, and the ferromagnetic film FM1 at respective portions thereof situated over the region CF1a of the conductive film CF1. At this step, as shown in FIG. 28, there are formed the magnetic recording layer MR1 formed of the ferromagnetic film FM1 at a portion thereof left over the region CF1a of the conductive film CF1, the tunnel barrier layer TB1 formed of the insulation film IF1 at a portion thereof left over the magnetic recording layer MR1, and the magnetization fixed layer MP1 formed of the ferromagnetic film FM2 at a portion thereof left over the tunnel barrier layer TB1. Further, there is formed the cap layer CL1 formed of the conductive film CF2 at a portion thereof left over the magnetization fixed layer MP1.

Further, the magnetic recording layer MR1, the tunnel barrier layer TB1, and the magnetization fixed layer MP1 form a magnetic memory element MM3.

Namely, in the step corresponding to Step S19, the conductive film CF2, the ferromagnetic film FM2, the insulation film IF1, and the ferromagnetic film FM1 are etched so that the cap layer CL1, the magnetization fixed layer MP1, the tunnel barrier layer TB1, and the magnetic recording layer MR1 are internally included in the base layer BF1 in a plan view.

Then, the same step as Step S20 of FIG. 5 is performed. As a result, as shown in FIG. 26, there are formed the interlayer insulation film IL11 and the plug PG2.

Then, over the interlayer insulation film IL11, there is formed a wire (not shown). By the steps up to this point, as shown in FIG. 26, there can be formed a magnetic memory element MM3. Incidentally, the manufacturing steps of the semiconductor device of the present Third Embodiment also have a step of, after the formation of the insulation film IF1, performing a heat treatment for crystallization of the ferromagnetic film FM1 and the insulation film IF1 as with the manufacturing steps of the semiconductor device of First Embodiment.

<Regarding the Material and the Composition Ratio of the Conductive Film and the MR Ratio>

Also in the present Third Embodiment, the relationship between the material and the composition ratio of the conductive film CF1 and the MR ratio can be set the same as the relationship between the material and the composition ratio of the conductive film CF1 and the MR ratio described by reference to FIGS. 12 and 13 in First Embodiment.

<Regarding the Relationship Between the Film Thickness of the Conductive Film and the Perpendicular Magnetization of the Ferromagnetic Film>

Also in the present Third Embodiment, the relationship between the film thickness of the conductive film CF1 and the perpendicular magnetization of the ferromagnetic film FM1 can be set the same as the relationship between the film thickness of the conductive film CF1 and the perpendicular magnetization of the ferromagnetic film FM1 described by reference to FIG. 25 in Second Embodiment.

<Main Features and Effects of the Present Embodiment>

The semiconductor device of the present Third Embodiment has, as with the semiconductor device of First Embodiment, a conductive film CF1 formed above a semiconductor substrate, a ferromagnetic film FM1 formed over the conductive film CF1, an insulation film IF1 formed over the ferromagnetic film FM1, and a ferromagnetic film FM2 formed over the insulation film IF1. The ferromagnetic film FM1, the insulation film IF1, and the ferromagnetic film FM2 form a magnetic memory element MM3 as a tunnel magnetoresistive effect element. The conductive film CF1 is formed of a metal nitride, or formed of a metal containing Xe. The ferromagnetic film FM1 contains Co, Fe, and B, and the insulation film IF1 contains MgO.

As a result, also in the semiconductor device of the present Third Embodiment, as with the semiconductor device of First Embodiment, the ferromagnetic film FM1 can have a body-centered cubic structure. This can increase the MR ratio of the tunnel magnetoresistive effect element formed of the ferromagnetic film FM1, the insulation film IF1, and the ferromagnetic film FM2. For this reason, it is possible to improve the performances of a semiconductor device including the magnetic memory element MM3.

On the other hand, in the semiconductor device of the present Third Embodiment, when a write current is passed, a current is not required to be passed through the magnetic recording layer MR1. For this reason, the film thickness of the base layer BF1 can be set large. In such a case, when the conductive film CF2, the ferromagnetic film FM2, the insulation film IF1, and the ferromagnetic film FM1 are etched, the conductive film CF1 can be allowed to function as an etching stopper. For this reason, by overetching the conductive film CF2, the ferromagnetic film FM2, the insulation film IF1, and the ferromagnetic film FM1, it is possible to remove the deposit deposited at, for example, the sidewall of the insulation film IF1. Therefore, the deposit deposited at the sidewall of the insulation film IF1, or the like can prevent a short circuit between the magnetization fixed layer MP1 and the magnetic recording layer MR1.

Up to this point, the invention completed by the present inventors was specifically described by way of embodiments. However, it is naturally understood that the present invention is not limited to the foregoing embodiments, and may be variously changed within the scope not departing from the gist thereof.

What is claimed is:

1. A semiconductor device, comprising:
a first conductive film formed above a semiconductor substrate;
a first ferromagnetic film formed over the first conductive film;
an insulation film formed over the first ferromagnetic film; and
a second ferromagnetic film formed over the insulation film,
wherein the first ferromagnetic film, the insulation film, and the second ferromagnetic film form a tunnel magnetoresistive effect element,
wherein the first conductive film is formed of a metal nitride,
wherein the first ferromagnetic film contains cobalt, iron, and boron, and
wherein the insulation film contains magnesium oxide.

2. The semiconductor device according to claim 1,
wherein the first conductive film is formed of tantalum nitride.

3. The semiconductor device according to claim 2,
wherein the composition ratio of nitrogen to tantalum in the first conductive film is 0.06 to 0.7.

4. The semiconductor device according to claim 1,
wherein the first ferromagnetic film is formed of a cobalt iron boron film having a (100)-oriented body-centered cubic structure, and
wherein the insulation film is formed of a magnesium oxide film having a (100)-oriented rock-salt structure.

5. The semiconductor device according to claim 1,
wherein the first conductive film includes a first region, and a second region situated on a first side of the first region, and
wherein the first ferromagnetic film is formed over the first region of the first conductive film.

6. The semiconductor device according to claim 5,
wherein the first conductive film includes a third region situated opposite to the second region across the first region,
wherein the first ferromagnetic film includes a fourth region over the first region of the first conductive film, a fifth region formed over the second region of the first conductive film, and a sixth region formed over the third region of the first conductive film,
wherein the insulation film is formed over the fourth region of the first ferromagnetic film, over the fifth region of the first ferromagnetic film, and over the sixth region of the first ferromagnetic film,
wherein the second ferromagnetic film is formed over the fourth region of the first ferromagnetic film via the insulation film,
wherein the fourth region of the first ferromagnetic film has a reversible first magnetization,
wherein the fifth region of the first ferromagnetic film has a second magnetization fixed in a first direction, and
wherein the sixth region of the first ferromagnetic film has a third magnetization fixed in a second direction in antiparallel with the first direction.

7. The semiconductor device according to claim 6, comprising:
a third ferromagnetic film formed under the second region of the first conductive film; and
a fourth ferromagnetic film formed under the third region of the first conductive film,
wherein in the fifth region of the first ferromagnetic film, the direction of the second magnetization is fixed in the first direction by the third ferromagnetic film, and
wherein in the sixth region of the first ferromagnetic film, the direction of the third magnetization is fixed in the second direction by the fourth ferromagnetic film.

8. The semiconductor device according to claim 7,
wherein a current is passed between the third ferromagnetic film and the fourth ferromagnetic film via the fourth region of the first ferromagnetic film, thereby resulting in a change in the direction of the first magnetization of the fourth region of the first ferromagnetic film.

9. The semiconductor device according to claim 5,
wherein the first conductive film includes a seventh region situated opposite to the second region across the first region,
wherein the first ferromagnetic film has a reversible fourth magnetization, and
wherein a current is passed between the second region of the first conductive film and the seventh region of the first conductive film via the first region of the first conductive film, thereby resulting in a change in the direction of the fourth magnetization of the first ferromagnetic film.

10. The semiconductor device according to claim 1,
wherein the first ferromagnetic film has a reversible fifth magnetization, and
wherein the second ferromagnetic film has a sixth magnetization fixed in a third direction.

11. The semiconductor device according to claim 10, comprising:
a second conductive film formed over the second ferromagnetic film,
wherein a current is passed between the first conductive film and the second conductive film via the first ferromagnetic film, thereby resulting in a change in the direction of the fifth magnetization of the first ferromagnetic film.

12. The semiconductor device according to claim 1,
wherein the first ferromagnetic film has a seventh magnetization fixed in a fourth direction, and
wherein the second ferromagnetic film has a reversible eighth magnetization.

13. A semiconductor device, comprising:
a first conductive film formed above a semiconductor substrate;
a first ferromagnetic film formed over the first conductive film;
an insulation film formed over the first ferromagnetic film; and
a second ferromagnetic film formed over the insulation film,
wherein the first ferromagnetic film, the insulation film, and the second ferromagnetic film form a tunnel magnetoresistive effect element,
wherein the first conductive film is formed of a metal containing xenon,
wherein the first ferromagnetic film contains cobalt, iron, and boron, and
wherein the insulation film contains magnesium oxide.

14. The semiconductor device according to claim 13,
wherein the first conductive film is formed of tantalum containing xenon.

15. A method for manufacturing a semiconductor device, comprising the steps of:
(a) forming a first conductive film above a semiconductor substrate;
(b) reforming the surface of the first conductive film;
(c) after the step (b), forming a first ferromagnetic film over the first conductive film;
(d) forming an insulation film over the first ferromagnetic film;
(e) forming a second ferromagnetic film over the insulation film; and
(f) after the step (d), performing a heat treatment for crystallization of the first ferromagnetic film and the insulation film,
wherein, in the step (a), the first conductive film formed of a metal or a metal nitride is formed,
wherein, in the step (c), the first ferromagnetic film containing, cobalt, iron, and boron is formed, and
wherein, in the step (d), the insulation film containing magnesium oxide is formed, and
wherein the first ferromagnetic film, the insulation film, and the second ferromagnetic film form a tunnel magnetoresistive effect element.

16. The method for manufacturing a semiconductor device according to claim 15,
wherein the step (b) includes the steps of:
(b1) oxidizing the surface of the first conductive film; and
(b2), after the step (b1), or with the step (b1), etching the surface of the first conductive film.

17. The method for manufacturing a semiconductor device according to claim 16,
wherein, in the step (a), with the semiconductor substrate not exposed to the air, the first conductive film is formed over the semiconductor substrate,
wherein, in the step (b1), the semiconductor substrate is exposed to the air, thereby to oxidize the surface of the first conductive film, and
wherein, in the step (b2), after the step (b1), the surface of the first conductive film is etched.
